(19) United States
(12) Patent Application Publication
(10) Pub. No.: US 2026/0198202 A1
(43) Pub. Date: Jul. 9, 2026

(54) DISPLAY DEVICE, ELECTRONIC APPARATUS INCLUDING THE SAME, AND METHOD OF MANUFACTURING THE DISPLAY DEVICE

(71) Applicant: Samsung Display Co., Ltd., Yongin-si (KR)

(72) Inventors: Seockhwan KANG, Yongin-si (KR); Kinyeng KANG, Yongin-si (KR); Hyoengki KIM, Yongin-si (KR); Hyuneok SHIN, Yongin-si (KR)

(73) Assignee: Samsung Display Co., Ltd., Yongin-si (KR)

(21) Appl. No.: 19/297,514

(22) Filed: Aug. 12, 2025

(30) Foreign Application Priority Data
Jan. 3, 2025 (KR) 10-2025-0001170

(51) Int. Cl. H10K 59/80; H10K 59/12; H10K 59/122

(52) U.S. Cl. CPC H10K 59/80522; H10K 59/1201; H10K 59/122

(57) ABSTRACT

A display device is provided. The display device includes: a substrate including a display area and a peripheral area that surrounds at least a portion of the display area; a plurality of display elements spaced apart in the display area of the substrate, each of the plurality of display elements including a first electrode, an intermediate layer, and a second electrode sequentially stacked; a bank layer on the first electrode of a first display element of the plurality of display elements and exposing a portion of the first electrode; a protective layer on the second electrode on the portion of the first electrode exposed through the bank layer; and an auxiliary electrode on and connected to the second electrode, wherein the auxiliary electrode is offset from the protective layer.

### CROSS-REFERENCE TO RELATED APPLICATION

This application is based on and claims priority to Korean Patent Application No. 10-2025-0001170, filed on January 3, 2025, in the Korean Intellectual Property Office, the disclosure of which is incorporated by reference herein in its entirety.

### BACKGROUND

The present invention relates to an apparatus and a method, and more particularly, to a display device, an electronic apparatus, and a method of manufacturing the display device.

Mobile electronic apparatuses are widely used. In addition to small electronic devices such as mobile phones, tablet personal computers (PCs) have become recently widely used as mobile electronic apparatuses.

To support various functions, for example, to provide a user with visual information, such as images, such mobile electronic apparatuses include a display device. Recently, as parts configured to drive a display device have been miniaturized, the proportion of the display device in an electronic apparatus has gradually increased and a structure that may bend to a preset angle with respect to a flat state is also under development.

### DISCLOSURE

### TECHNICAL PROBLEM

Generally, a display device may include a display area in which display elements implementing images are disposed. To implement images, a power voltage may be applied to the display elements. A voltage drop occurs in a region of the display area due to a resistance of an electrode to which the power voltage is applied, and brightness of the region of the display area may be reduced. Accordingly, the display device may not provide clear images.

### TECHNICAL SOLUTION

One or more embodiments provide a display device capable of providing clear images, an electronic apparatus including the same, and a method of manufacturing the display device.

According to an aspect of an embodiment, a display device includes: a substrate including a display area and a peripheral area that surrounds at least a portion of the display area; a plurality of display elements spaced apart in the display area of the substrate, each of the plurality of display elements including a first electrode, an intermediate layer, and a second electrode sequentially stacked; a bank layer on the first electrode of a first display element of the plurality of display elements and exposing a portion of the first electrode; a protective layer on the second electrode on the portion of the first electrode exposed through the bank layer; and an auxiliary electrode on and connected to the second electrode, wherein the auxiliary electrode is offset from the protective layer.

The auxiliary electrode may include a same material as the second electrode.

The auxiliary electrode and the second electrode may include different materials.

At least a portion of a planar shape of the auxiliary electrode may have an island shape, a mesh shape, a serpentine shape, and/or a line shape.

A planar shape of a region through which the bank layer exposes the first electrode may be inside a planar shape of the protective layer.

The display device may further include a capping layer on the protective layer and the auxiliary electrode.

The protective layer may shield at least one of the plurality of display elements.

The auxiliary electrode may include: a plurality of first auxiliary electrodes; and a second auxiliary electrode connecting one of the plurality of first auxiliary electrodes to another of the plurality of first auxiliary electrodes.

The second electrode may shield an entire surface of the display area.

At least a portion of a planar shape of the protective layer may have an island shape, a line shape, a serpentine shape, and/or a mesh shape.

According to another aspect of an embodiment, a method of manufacturing a display device, includes: sequentially disposing, on a substrate, a first electrode, a bank layer exposing at least a portion of the first electrode, an intermediate layer, and a second electrode; disposing a protective layer on a first portion of the second electrode and the first electrode exposed through the bank layer; and disposing an auxiliary electrode on a second portion of the second electrode that is offset from the first electrode exposed through the bank layer, wherein the auxiliary electrode is formed by disposing, on the second portion of the second electrode, an auxiliary electrode-forming material that forms the auxiliary electrode.

The disposing of the protective layer may include: disposing a first mask defining a first opening to face the bank layer, wherein the first opening corresponds to the first portion of the second electrode; and forming the protective layer on the first portion of the second electrode by passing a first deposition material through the first opening.

The disposing of the protective layer may include disposing, on the first portion of the second electrode, a protective layer-forming material using inkjet printing.

The disposing of the protective layer on the portion of the second electrode disposed on the first electrode may include: disposing photoresist on an entire surface of the second electrode; forming an opening area in the photoresist to correspond to the first portion of the second electrode; and disposing a protective layer-forming material in the opening area.

The disposing of the protective layer may include: disposing a protective layer-forming material on an entire surface of the second electrode; disposing a blocking layer on a portion of the protective layer-forming material corresponding to the first portion of the second electrode; and removing a remaining portion of the protective layer-forming material other than the portion of the protective layer-forming material disposed under the blocking layer.

The second electrode and the auxiliary electrode may include different materials.

At least a portion of a planar shape of the auxiliary electrode and/or at least a portion of a planar shape of the protective layer may have an island shape, a mesh shape, a serpentine shape, and/or a line shape.

A planar shape of a region through which the bank layer exposes the first electrode may be inside a planar shape of the protective layer.

The method may further include disposing a capping layer on the protective layer and the auxiliary electrode.

The disposing of the auxiliary electrode on the second portion of the second electrode may include: disposing a second mask to face the substrate, wherein the second mask defines a second opening corresponding to an entire surface of the second electrode; supplying the auxiliary electrode-forming material toward the second mask; and disposing, on the second electrode and the protective layer, the auxiliary electrode-forming material passing through the second opening.

The disposing of the auxiliary electrode on the second portion of the second electrode may include: disposing a second mask defining a plurality of second openings to face the substrate, wherein at least one of the plurality of second openings corresponds to the second portion of the second electrode; supplying the auxiliary electrode-forming material toward the second mask; disposing, on the second portion of the second electrode, the auxiliary electrode-forming material passing through the plurality of second openings; moving the second mask in one direction by a preset distance; supplying the auxiliary electrode-forming material toward the second mask; and disposing, in another region of the second electrode offset from the second portion, the auxiliary electrode-forming material passing through the plurality of second openings.

The auxiliary electrode disposed on the second portion of the second electrode may be connected to another portion of the auxiliary electrode.

The disposing of the auxiliary electrode on the second portion of the second electrode may include disposing, on the second electrode and the protective layer, the auxiliary electrode-forming material using inkjet printing.

According to another aspect of an embodiment, a method of manufacturing a display device, includes: sequentially disposing, on a substrate, a first electrode, a bank layer exposing at least a portion of the first electrode, an intermediate layer, and a second electrode; and disposing an auxiliary electrode on at least a second portion of the second electrode different from a first portion of the second electrode disposed on the first electrode exposed through the bank layer. The disposing the auxiliary electrode may include a deposition process of disposing, on the second electrode, a deposition material passing through a second mask defining a second opening corresponding to the second portion of the second electrode, a process of forming the auxiliary electrode on an entire surface of the second electrode and removing a portion of the auxiliary electrode, and/or a process of disposing, on at least a portion of the second portion of the second electrode, the auxiliary electrode using inkjet printing.

The deposition process of disposing, on the second electrode, the deposition material passing through the second mask may include: disposing the second mask to face the substrate, wherein the second mask defines a plurality of second openings, at least one of which corresponds to the second portion of the second electrode; supplying the deposition material toward the second mask; disposing, on the second portion of the second electrode, the deposition material passing through the second opening; moving the second mask in one direction by a preset distance; supplying the deposition material toward the second mask; and disposing, on another region different of the second electrode offset from the second portion, the deposition material passing through the second opening.

The process of forming the auxiliary electrode on the entire surface of the second electrode and removing a portion of the auxiliary electrode may include: disposing the auxiliary electrode on the entire surface of the second electrode; disposing photoresist on the auxiliary electrode to expose the auxiliary electrode disposed on the first electrode exposed through the bank layer to the outside; removing a portion of the auxiliary electrode exposed to the outside; and removing the photoresist.

The auxiliary electrode may define an opening corresponding to a region through which the bank layer exposes the first electrode.

According to another aspect of an embodiment, an electronic apparatus includes a display device, wherein the display device includes: a substrate including a display area and a peripheral area that surrounds at least a portion of the display area; a plurality of display elements spaced apart from in the display area of the substrate, each of the plurality of display elements including a first electrode, an intermediate layer, and a second electrode sequentially stacked; a bank layer on the first electrode of a first display element of the plurality of display elements and exposing a portion of the first electrode; a protective layer on the second electrode on the portion of the first electrode exposed through the bank layer; and an auxiliary electrode on and connected to the second electrode, wherein the auxiliary electrode is offset from the protective layer.

The auxiliary electrode may include a same material as the second electrode.

The auxiliary electrode and the second electrode may include different materials.

At least a portion of a planar shape of the auxiliary electrode may have an island shape, a mesh shape, a serpentine shape, and/or a line shape.

A planar shape of a region through which the bank layer exposes the first electrode may be inside a planar shape of the protective layer.

The display device may further include a capping layer on the protective layer and the auxiliary electrode.

The protective layer may shield at least one of the plurality of display elements.

The auxiliary electrode may include: a plurality of first auxiliary electrodes apart; and a second auxiliary electrode connecting one of the plurality of first auxiliary electrodes to another of the plurality of first auxiliary electrodes.

The second electrode may shield an entire surface of the display area.

At least a portion of a planar shape of the protective layer may have an island shape, a line shape, a serpentine shape, and/or a mesh shape.

According to another aspect of an embodiment, a display device includes: a plurality of display elements on a substrate, a first display element of the plurality of display elements including a first electrode, a second electrode, and an intermediate layer between the first electrode and the second electrode; a bank layer on the first electrode and defining an opening, through which a portion of the first electrode is exposed; a protective layer on the second electrode on the portion of the first electrode exposed through the bank layer; and an auxiliary electrode on and connected to the second electrode, wherein the auxiliary electrode is offset from the protective layer.

The display device may further include a capping layer on the protective layer and the auxiliary electrode.

A side surface of the auxiliary electrode may face a side surface of the protective layer.

A side surface of the auxiliary electrode may be in direct contact with a side surface of the protective layer.

The auxiliary electrode and the protective layer may have a common thickness.

The auxiliary electrode may have a mesh shape that defines a plurality of openings respectively corresponding to the plurality of display elements.

The auxiliary electrode may be electrically connected to the second electrode.

The plurality of display elements may include a second display element including another first electrode, another second electrode, and another intermediate layer between the other first electrode and the other second electrode, and the auxiliary electrode may electrically connect the second electrode of the first display element and the other second electrode of the second display element.

Aspects, features, and advantages other than the above described things will become apparent from the following detailed description of the invention, the accompanying drawings, and claims.

These general and specific aspects may be implemented by using a system, a method, a computer program, or a combination of a certain system, method, and computer program.

### EFFECTS OF INVENTION

A display device and an electronic apparatus according to one or more embodiments may reduce an IR-drop. In addition, a display device and an electronic apparatus according to one or more embodiments may provide clear images.

A method of manufacturing a display device according to one or more embodiments may accurately form an auxiliary electrode at a desired position. In addition, a method of manufacturing a display device according to one or more embodiments may manufacture a display device providing clear images.

### BRIEF DESCRIPTION OF DRAWINGS

The above and other aspects will be more apparent from the following description of embodiments taken in conjunction with the accompanying drawings.

FIG. 1 is a schematic perspective view of an electronic apparatus according to an embodiment.

FIG. 2 is a schematic exploded perspective view of the electronic apparatus of FIG. 1.

FIG. 3 is a schematic diagram of the electronic apparatus of FIG. 1.

FIG. 4 is a schematic plan view of a display device according to an embodiment.

FIG. 5 is a schematic side view of the display device of FIG. 4.

FIG. 6 is a schematic plan view of the display device of FIG. 4.

FIG. 7 is an equivalent circuit diagram of a sub-pixel disposed in a display area of the display device of FIG. 4.

FIG. 8 is a schematic enlarged plan view of a region B of FIG. 6.

FIG. 9A is a schematic cross-sectional view taken along line C-C’ of FIG. 8.

FIG. 9B is a schematic cross-sectional view of a region E of FIG. 9A.

FIG. 10A is a schematic cross-sectional view showing an apparatus for manufacturing a first display device according to an embodiment.

FIG. 10B is a schematic perspective view of a first mask assembly shown in FIG. 10A.

FIG. 10C is a schematic cross-sectional view showing a part of a method of manufacturing a display device according to an embodiment.

FIG. 11A is a schematic cross-sectional view showing a part of a method of manufacturing a display device according to another embodiment.

FIG. 11B is a schematic cross-sectional view showing a part of a method of manufacturing a display device according to another embodiment.

FIG. 11C is a schematic cross-sectional view showing a part of a method of manufacturing a display device according to another embodiment.

FIG. 12 is a schematic cross-sectional view showing a part of a method of manufacturing a display device according to another embodiment.

FIG. 13 is a schematic cross-sectional view showing a part of a method of manufacturing a display device according to another embodiment.

FIGS. 14A and 14B are schematic perspective views of a second mask assembly of an apparatus for manufacturing a second display device according to an embodiment.

FIG. 15 is a schematic plan view of a portion of a display area of a display device according to another embodiment.

FIG. 16 is a schematic plan view of a portion of a display area of a display device according to another embodiment.

FIG. 17 is a schematic plan view of a portion of a display area of a display device according to another embodiment.

FIG. 18 is a schematic plan view of a portion of a display area of a display device according to another embodiment.

FIG. 19 is a schematic plan view of a portion of a display area of a display device according to another embodiment.

FIG. 20 is a schematic plan view of a portion of a display area of a display device according to another embodiment.

FIG. 21A is a schematic plan view of a portion of an apparatus for manufacturing a second display device according to another embodiment.

FIG. 21B is a schematic plan view showing a part of a display device according to another embodiment.

FIG. 22 is a cross-sectional view of a portion of a display device according to another embodiment.

FIGS. 23A, 23B and 23C are schematic plan views showing a part of a method of manufacturing a display device according to another embodiment.

FIGS. 24A, 24B and 24C are schematic cross-sectional views showing a part of a method of manufacturing a display device according to another embodiment.

FIG. 25 is a block diagram of an electronic apparatus according to an embodiment.

FIGS. 26 to 28 are schematic views of an electronic apparatus according to various embodiments.

### DETAILED DESCRIPTION

Hereinafter, embodiments are described in detail with reference to the accompanying drawings. As the present invention allows for various changes and numerous embodiments, certain embodiments will be illustrated in the drawings and described in the detailed description. Effects and features of the present invention, and methods for achieving them will be clarified with reference to embodiments described below with reference to the drawings. However, the present invention is not limited to embodiments described below and may be implemented in various forms. Each embodiment provided in the following description is not excluded from being associated with one or more features of another example or another embodiment also provided herein or not provided herein but consistent with the present disclosure.

Similar or corresponding elements are given similar reference characters when describing with reference to the drawings, and a repeated description thereof is omitted.

In embodiments below, such terms as first and second are not used in a limited meaning and are used for the purpose of distinguishing one element from another.

In embodiments below, the singular expressions include the plural expressions unless the context clearly indicates otherwise.

In embodiments below, the terms “comprise,” or “include” as used herein specify the presence of stated features or elements but do not preclude the addition of one or more other features or elements.

In embodiments below, when a layer, region, or element is referred to as being on another portion, it may include not only a case where the layer, region, or element is directly on the other portion, but also a case where intervening layers, regions, or elements are disposed therebetween. By contrast, when a layer, region, or element is referred to as being directly on another portion, there are no intervening layers, regions, or elements present.

Sizes of elements in the drawings may be exaggerated or reduced for convenience of explanation. As an example, the size and thickness of each element shown in the drawings are arbitrarily represented for convenience of description, and thus, the present invention is not necessarily limited thereto.

In an embodiment below, an x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially and performed in the opposite order of the described order.

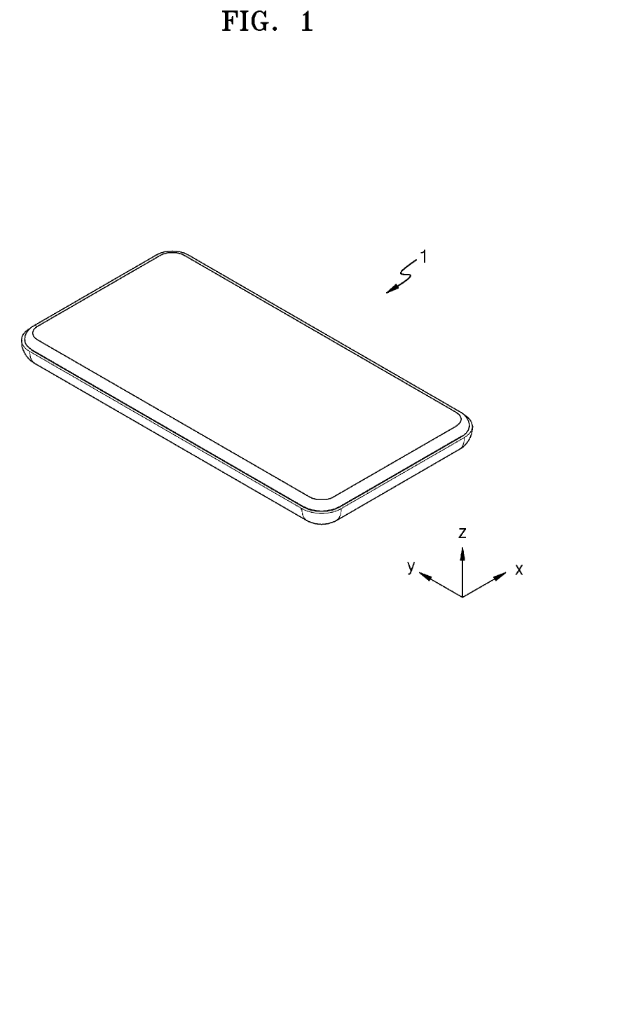

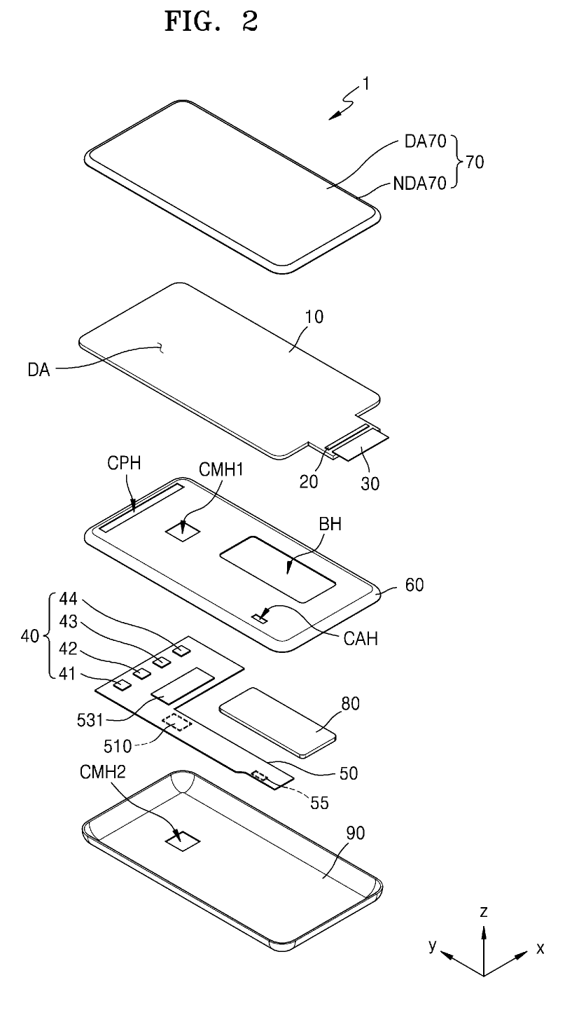

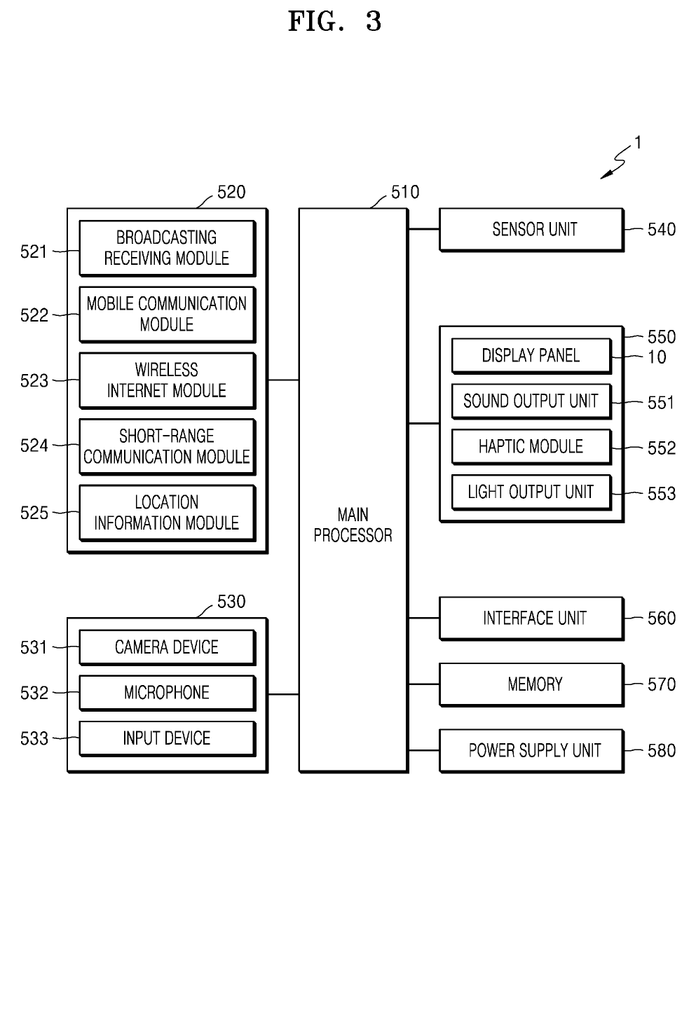

FIG. 1 is a schematic perspective view of an electronic apparatus 1 according to an embodiment, FIG. 2 is a schematic exploded perspective view of the electronic apparatus 1 of FIG. 1, and FIG. 3 is a schematic block diagram of the electronic apparatus 1 of FIG. 1.

Referring to FIGS. 1 to 3, the electronic apparatus 1 may include an apparatus for displaying moving images or still images and may be used as one of various products including televisions, notebook computers, monitors, advertisement boards, Internet of things (IoTs) devices as well as portable electronic apparatuses including mobile phones, smart phones, tablet personal computers (PCs), mobile communication terminals, electronic organizers, electronic books, portable multimedia players (PMPs), navigations, or ultra mobile personal computers (UMPCs). In addition, the electronic apparatus 1 according to an embodiment may be used as a wearable device such as a smart watch, watch phone, glasses-type display, or head-mounted display (HMD). In addition, the electronic apparatus 1 according to an embodiment may be used as an instrument panel for an automobile, a center fascia for an automobile, a center information display (CID) arranged on a dashboard, a room mirror display, a mirror display replaces a side mirror of an automobile, and a display arranged on the backside of a front seat as an entertainment display for a back seat of an automobile.

For convenience of description, the electronic apparatus 1 according to an embodiment is illustrated in FIGS. 1 and 2 as a smartphone. The electronic apparatus 1 may include a cover window 70, a display device 10, a data driver 20, a display circuit board 30, a component 40, a bracket 60, a main circuit board 50, a battery 80, and/or a lower cover 90.

In a plan view of the present specification, “left”, “right”, “up”, and “down” denote directions when the display device 10 is viewed in a direction perpendicular to the display device 10. As an example, “left” denotes a -x direction, “right” denotes a +x direction, “up” denotes a +y direction, and “down” denotes a -y direction.

The electronic apparatus 1 may be shown to have a roughly rectangular shape in a plan view. As an example, as shown in FIG. 1, the electronic apparatus 1 may have a roughly rectangular shape having short sides in an x axis direction and long sides in a y axis direction in an xy-plane. In this case, an edge where a short side in the x axis direction meets a long side in the y axis direction may form a right angle or have a round shape with a preset curvature. In a plan view, the shape of the electronic apparatus 1 is not limited to a rectangle, and may include other polygonal, elliptical, or irregular shapes.

The cover window 70 may be disposed on the display device 10 to cover the upper surface of the display device 10. The cover window 70 may be configured to protect the upper surface of the display device 10.

The cover window 70 may include a transmissive cover portion DA70 and a light-blocking cover portion NDA70, wherein the transmissive cover portion DA70 corresponds to the display device 10, and the light-blocking cover portion NDA70 surrounds the transmissive cover portion DA70. The light-blocking cover portion NDA70 may include an opaque material (e.g., a colored opaque material) that blocks light. The light-blocking cover portion NDA70 may include a pattern that is visible to a user when no image is displayed.

The display device 10 may be disposed under the cover window 70. The display device 10 may overlap the transmissive cover portion DA70 of the cover window 70. The display device 10 may include a display area DA. The display area DA is a region in which images are displayed, and may include a region (referred to as a component area, hereinafter) that transmits light emitted from the components 40 disposed below the display device 10. The component may include sensors and cameras that use visible light, infrared light, sound, and the like.

The display device 10 may be a light-emitting display device including a light-emitting diode. The light-emitting diode may include an organic light-emitting diode including an organic emission layer, or an inorganic light-emitting diode including an inorganic material. The inorganic light-emitting diode may include a PN diode including inorganic material semiconductor-based materials. When a forward voltage is applied to a PN-junction diode, holes and electrons are injected, and light of a preset color may be emitted while energy released by recombination of the holes and the electrons is converted to light energy. The inorganic light-emitting diode may have a width of several micrometers to hundreds of micrometers. The inorganic light-emitting diode may be denoted by a micro light-emitting diode.

The display device 10 may be a rigid display device that has rigidity and thus is not easily bent, or a flexible display device that has flexible and thus is easily bendable, foldable, or rollable. As an example, the display device 10 may include a foldable display device that is foldable (i.e., may be folded and unfolded), a curved display device that has a curved display surface, a bended display device in which a region except a display surface is bent, a rollable display device that is rollable and unrollable, or a stretchable display device that is stretchable.

The display device 10 may be a transparent display device such that an object or background disposed below the display device 10 is viewable from the upper surface of the display device 10. Alternatively, the display device 10 may be a reflective display device that may reflect an object or background over the upper surface of the display device 10.

The data driver 20 may be mounted in the form of an integrated circuit (IC) on the display device 10. However, embodiments are not limited thereto. As an example, the data driver 20 may be mounted on the display circuit board 30.

The display circuit board 30 may be attached to one side of the display device 10. The display circuit board 30 may be a flexible printed circuit board (FPCB) that may be bent, a rigid printed circuit board (PCB) that is rigid and is not easily bendable, or a composite printed circuit board including both an FPCB and a rigid PCB. A touch sensor driver may be mounted on the display circuit board 30. The touch sensor driver may include an integrated circuit. The touch sensor driver may be electrically connected to touch electrodes of a touchscreen layer of the display device 10 through the display circuit board 30.

The touchscreen layer of the display device 10 may sense a user’s touch input by using at least one of various touch methods such as a resistance layer method, a capacitance method and the like. In the case where the touchscreen layer of the display device 10 senses a user’s touch input by using a capacitance method, the touch sensor driver may determine whether a user touches the touch sensor layer by applying driving signals to driving electrodes among touch electrodes, and sensing voltages charged in a mutual capacitance between the driving electrodes and the sensing electrodes through the sensing electrodes among the touch electrodes.

A user’s touch may include a contact touch and a proximity touch. The contact touch denotes that an object such as a user’s finger or a pen is in direct contact with the cover window 70 disposed on the touchscreen layer. The proximity touch, like hovering, denotes that an object such as a user’s finger or a pen is located near over the cover window 70, while being spaced apart from the cover window 70. The touch sensor driver may be configured to transfer sensor data to a main processor 510 according to sensed voltages, and the main processor 510 may be configured to calculate touch coordinates at which a touch input occurs by analyzing the sensor data.

A controller may be disposed on the display circuit board 30, wherein the controller is configured to supply driving voltages for driving pixels of the display device 10, a gate driver, and/or the data driver 20.

The bracket 60 for supporting the display device 10 may be disposed under the display device 10. The bracket 60 may include plastic, metal, or both plastic and metal. The bracket 60 may have (i.e., define) a first camera hole CMH1 into which a camera device 531 is inserted, a battery hole BH in which the battery 80 is disposed, a cable hole CAH through which a cable connected to the display circuit board 30 passes, and a component hole CPH corresponding to the components 40. The component hole CPH may overlap the components 40 of the main circuit board 50 when viewed in a third direction (a z axis direction). For reference, the display area DA of the display device 10 may overlap the components 40 of the main circuit board 50 when viewed in the third direction (the z axis direction). When needed, the bracket 60 may not have the component hole CPH.

The components 40 of the electronic apparatus 1 may include a first component 41, a second component 42, a third component 43, and a fourth component 44 which overlap the display device 10. Each of the first component 41, the second component 42, the third component 43, and the fourth component 44 may include at least one of a proximity sensor, an illumination sensor, an iris sensor, a face recognition sensor, and a camera (or an image sensor). A proximity sensor that uses an infrared ray may detect an object located close to the upper surface of the electronic apparatus 1, and an illumination sensor may detect brightness of light incident to the upper surface of the electronic apparatus 1. In addition, an iris sensor may capture a person’s iris located over the upper surface of the electronic apparatus 1, and a camera may receive image data of an object disposed on the upper surface of the electronic apparatus 1. The components 40 are not limited to the proximity sensor, the illumination sensor, the iris sensor, the face recognition sensor, and the camera, and may include other sensors.

The main circuit board 50 and the battery 80 may be disposed under the bracket 60. The main circuit board 50 may be a printed circuit board or a flexible printed circuit board.

The main circuit board 50 may include the main processor 510, the camera device 531, a main connector 55, and the components 40. The main processor 510 may include an integrated circuit. When needed, the electronic apparatus 1 may include not only the camera device 531 disposed on the upper surface of the main circuit board 50 but also a camera device disposed on the lower surface of the main circuit board 50. Each of the main processor 510 and the main connector 55 may be disposed on one of the upper surface and lower surface of the main circuit board 50. The main circuit board 50 may be electrically connected to the display circuit board 30 through the main connector 55 and the like.

The main processor 510 may control all functions of the electronic apparatus 1. As an example, the main processor 510 may be configured to output digital video data to the data driver 20 through the display circuit board 30 such that the display device 10 displays images. The main processor 510 may be configured to receive sensed data from the touch sensor driver. The main processor 510 may determine whether a user touches a touchscreen according to sensed data, and execute an operation corresponding to a user’s direct touch or proximity touch. The main processor 510 may be an application processor including an integrated circuit, a central processing unit, or a system chip.

The camera device 531 processes image frames such as still images or moving images obtained by an image sensor in a camera mode, and outputs the image frames to the main processor 510. The camera device 531 may include at least one of a camera sensor (e.g., a charge-coupled device (CCD), a complementary metal oxide semiconductor (CMOS), and the like), a photo sensor (or an image sensor), and a laser sensor.

A cable passing through the cable hole CAH of the bracket 60 may be connected to the main connector 55, and the main circuit board 50 may be electrically connected to the display circuit board 30 through this cable.

The electronic apparatus 1 may be represented by a block diagram as shown in FIG. 3. The electronic apparatus 1 may be represented as including, in addition to the main processor 510, a wireless communication unit (e.g., wireless communication device) 520, an input unit (e.g., input device) 530, a sensor unit (e.g., sensor device) 540, an output unit (e.g., output device) 550, an interface unit (e.g., interface) 560, a memory 570, and/or a power supply unit (e.g., power supply device) 580 shown in FIG. 3.

The wireless communication unit 520 may include at least one of a broadcasting receiving module 521, a mobile communication module 522, a wireless Internet module 523, a short-range communication module 524, and a location information module 525.

The broadcasting receiving module 521 is configured to receive broadcasting signals and/or broadcasting-related information from an external broadcasting management server through a broadcasting channel. The broadcasting channel may include satellite channels or groundwave channels.

The mobile communication module 522 is configured to transmit/receive wireless signals to/from at least one of a base station, an external terminal, and a server on a mobile communication network established according to technology standards for mobile communication or communication schemes (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and the like). Wireless signals may include voice call signals, image communication call signals, or various types of data corresponding to text/multimedia message transmission/reception.

The wireless Internet module 523 denotes a module for wireless Internet access. The wireless Internet module 523 may be configured to transmit/receive wireless signals on a communication network according to wireless Internet technologies. Examples of wireless Internet technologies may include wireless local area network (WLAN), wireless-fidelity (Wi-Fi), Wi-Fi Direct, and/or digital living network alliance (DLNA).

The short-range communication module 524 is for short-range communication, and may support short range communication by using at least one of Bluetooth^{TM}, Radio Frequency Identification (RFID), Infrared Data Association; IrDA (IrDA), Ultra-Wideband (UWB), ZigBee, Near Field Communication (NFC), Wi-Fi, Wi-Fi Direct, and Wireless Universal Serial Bus (Wireless USB) technologies. The short-range communication module 524 may support wireless communication between the electronic apparatus 1 and a wireless communication system, between the electronic apparatus 1 and another electronic apparatus, or between the electronic apparatus 1 and a network in which another electronic apparatus (or an external server) is located, through a short-range wireless area network. The short-range wireless area network may be a wireless personal area network. The other electronic apparatus may be a wearable device that may exchange data, or operate with the electronic apparatus 1.

The location information module 525, which is a module for obtaining a location of the electronic apparatus 1, may include a global positioning system (GPS) module or a Wi-Fi module.

The input unit 530 may include an image input device such as the camera device 531 for inputting image signals, a sound input unit such as a microphone 532 for inputting sound signals, and an input device 533 for receiving information from a user. The camera device 531 processes image frames such as still images or moving images obtained by an image sensor in an image communication mode or a capturing mode. The processed image frames may be displayed on the display device 10 or stored in the memory 570. The microphone 532 processes external sound signals as electrical voice data. The processed voice data may be variously utilized according to a function (or an application in execution) being performed in the electronic apparatus 1.

The main processor 510 may control an operation of the electronic apparatus 1 to correspond to information input through the input device 533. The input device 533 may include a mechanical input component, such as buttons, a dome switch, a jog wheel, a jog switch, and the like, or a touch input component located on the lower surface or the lateral surface of the electronic apparatus 1. The touch input component may include a touchscreen layer of the display device 10.

The sensor unit 540 may include at least one sensor that senses at least one of information inside the electronic apparatus 1, peripheral environmental information surrounding the electronic apparatus 1, and user information, and generates sensing signals corresponding thereto. The main processor 510 may control driving or an operation of the electronic apparatus 1 based on the sensing signals, or perform data processing, a function, or an operation related to an application disposed in the electronic apparatus 1. The sensor unit 540 may be a proximity sensor, an illumination sensor, or a face recognition sensor as described above with regard to the component 40. The sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. In addition, the sensor unit 540 may include an environmental sensor or a chemical sensor. The environmental sensors may include, for example, a barometer, a hygrometer, a thermometer, a radiation detection sensor, a heat detection sensor, and/or a gas detection sensor. Chemical sensors may include, for example, an electronic nose, a healthcare sensor, and/or a biometric recognition sensor.

The output unit 550 is for generating an output related to a visual sense, an auditory sense, or a tactile sense, and may include at least one of the display device 10, a sound output unit 551, a haptic module 552, and a light output unit 553.

The display device 10 displays (outputs) information processed by the electronic apparatus 1. As an example, the display device 10 may display execution screen information of an application driven by the electronic apparatus 1, user interface (UI), or graphic user interface (GUI) information corresponding to the execution screen information. The display device 10 may include a display layer and the touchscreen layer, wherein the display layer displays images, and the touchscreen layer senses a user’s touch input. Accordingly, the display device 10 may serve as one of the input devices 533 that provide an input interface between the electronic apparatus 1 and a user, and simultaneously, serve as one of the output units 550 that provide an output interface between the electronic apparatus 1 and a user.

The sound output unit 551 may output sound data received by the wireless communication unit 520 or stored in the memory 570 in a call reception mode, a communication mode or recoding mode, a voice recognition mode, a broadcasting reception mode, and the like. The sound output unit 551 may output sound signals related to a function (e.g., a call signal reception tone, a message reception tone, and the like) performed by the electronic apparatus 1. The sound output unit 551 may include a receiver and a speaker. At least one of the receiver and the speaker may be a sound generator that is attached under the display device 10 and vibrates the display device 10 to output sounds. The sound generator may be a piezoelectric element or a piezoelectric actuator that contracts and expands according to electrical signals, or an exciter that generates magnetic force by using a voice coil to vibrate the display device 10.

The haptic module 552 generates various haptic effects that may be felt by a user. The haptic module 552 may provide vibrations to a user as a haptic effect. The haptic module 552 may not only transfer a tactile effect through a direct contact but implement a tactile effect such that a user may feel the tactile effect through a muscle sense in fingers or arms.

The light output unit 553 outputs signals for informing occurrence of an event by using light of a light source. Examples of an event generated in the electronic apparatus 1 may include message reception, call signal reception, a missed call, alarm, schedule notification, e-mail reception, and/or information reception through an application, and the like. Signals output by the light output unit 553 are implemented when the electronic apparatus 1 emits light of a single color or a plurality of colors to the front surface or the rear surface. The signal output may end when the electronic apparatus 1 detects that a user confirms an event.

The interface unit 560 serves as a path with various kinds of external apparatuses connected to the electronic apparatus 1. The interface unit 560 may include at least one of a wired/wireless headset port, an external charger port, a wired/wireless data port, a memory card part, a port for connecting an apparatus having an identification module, an audio input/output (I/O) port, a video I/O port, and an earphone port. When an external apparatus is connected to the interface unit 560, the electronic apparatus 1 may perform an appropriate control related to the external apparatus connected.

The memory 570 stores data that support various functions of the electronic apparatus 1. The memory 570 may store a plurality of application programs driven in the electronic apparatus 1, data and/or commands for operations of the electronic apparatus 1. At least some of the plurality of application programs may be downloaded from an external server through wireless communication. The memory 570 may store an application program for operations of the main processor 510, and temporarily store data input/output, for example, data such as a phone book, messages, still images, and/or moving images. In addition, the memory 570 may store haptic data for various patterns of vibrations provided to the haptic module 552, and sound data regarding various sounds provided to the sound output unit 551.

The memory 570 may include at least one type of storing medium among a flash memory type, a hard disk type, a solid state disk (SSD) type, a silicon disk drive (SDD) type, a multimedia card micro type, a card type memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply unit 580 receives an external power and/or an internal power under control of the main processor 510, and supplies power to respective elements included in the electronic apparatus 1. The power supply unit 580 may include the battery 80. In addition, the power supply unit 580 may include a connection port. The connection port may be an example of the interface unit 560 to which an external charger is electrically connected, wherein the external charger supplies power to charge the battery 80. Alternatively, the power supply unit 580 may charge the battery 80 wirelessly. The battery 80 may be arranged not to overlap the main circuit board 50 in the third direction (the z direction). The battery 80 may overlap the battery hole BH of the bracket 60.

The lower cover 90 may form an exterior of the electronic apparatus 1 and have (i.e., define) an opening exposing a portion of the display device 10. The lower cover 90 has an open shape corresponding to the display device 10 and may be fastened to the display device 10. The lower cover 90 may be located on the opposite side of the cover window 70 with the display device 10 therebetween. The lower cover 90 may be disposed under the main circuit board 50 and the battery 80. The lower cover 90 may be fastened and fixed to the bracket 60. The lower cover 90 may form the lower exterior of the electronic apparatus 1. The lower cover 90 may include plastic, metal, or both plastic and metal.

A second camera hole CMH2 through which the lower surface of the camera device 531 is exposed may be formed in the lower cover 90. The positions of the camera device 531 and the first and second camera holes CMH1 and CMH2 corresponding to the camera device 531 are not limited to the embodiment shown in FIG. 2, but may be variously modified.

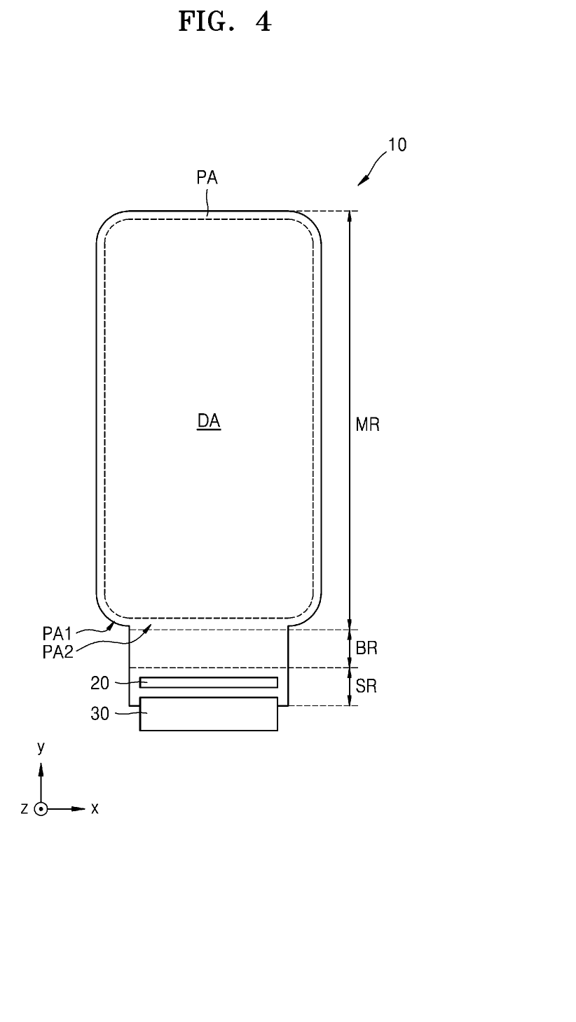

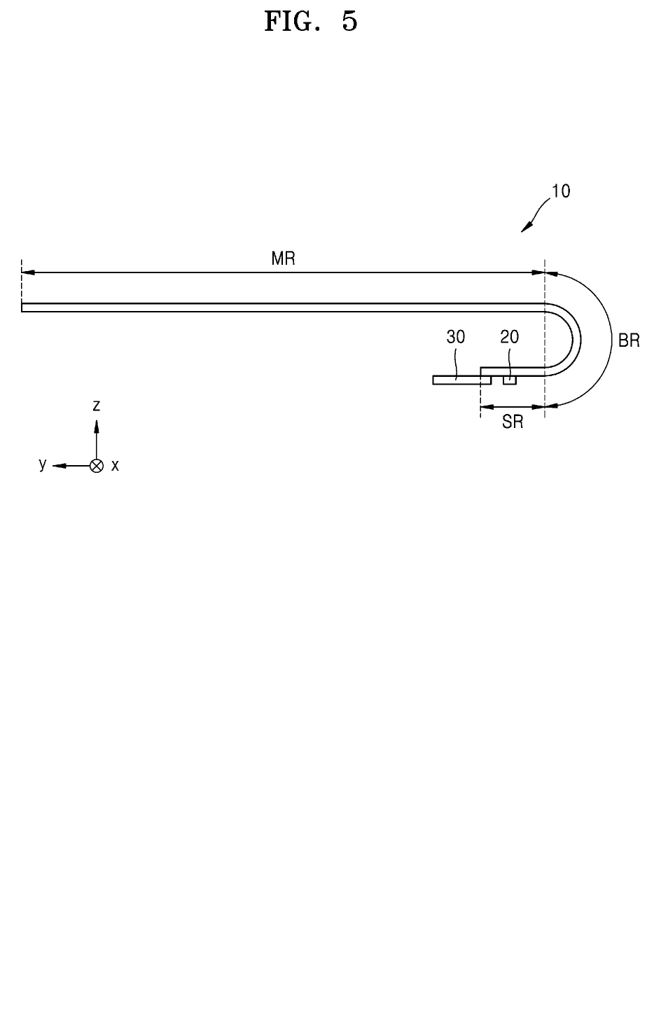

FIG. 4 is a schematic plan view of the display device 10 according to an embodiment, and FIG. 5 is a schematic side view of the display device 10 of FIG. 4. The electronic apparatus 1 may include the display device 10 shown in FIGS. 4 and 5.

The display device 10 may include the display area DA and a peripheral area PA outside the display area DA. The display area DA is a region in which images are displayed and a plurality of pixels may be disposed. The display area DA may have various shapes, for example, circular shapes, elliptical shapes, polygonal shapes, or shapes of specific figures. It is shown in FIG. 4 that the display area DA has a roughly rectangular shape having round corners.

The peripheral area PA may be disposed outside the display area DA. The peripheral area PA may include a first peripheral area PA1 and a second peripheral area PA2, wherein the first peripheral area PA1 is disposed to surround at least a portion of the display area DA, and the second peripheral area PA2 is located at the lower end of the display area DA and extends in a first direction (e.g., an x axis direction). The width of the second peripheral area PA2 in the first direction (e.g., the x axis direction) may be less than the width of the display area DA. At least a portion of the second peripheral area PA2 may be easy to bend through this structure.

A planar shape of the display device 10 shown in FIG. 4 may be substantially equal to the shape of the substrate 100 included in the display device 10. When the display device 10 includes the display area DA and the peripheral area PA outside the display area DA, it may represent a substrate 100 includes the display area DA and the peripheral area PA outside the display area DA. Hereinafter, for convenience, description is made on the assumption that the substrate 100 includes the display area DA and the peripheral area PA.

The display device 10 may include a main region MR, a bent region BR outside the main region MR, and a sub-region SR apart from the main region MR with the bent region BR therebetween. The main region MR may be disposed on one side of the bent region BR, and the sub-region SR may be disposed on the other side of the bent region BR. The display device 10 may be bent in the bent region BR, as shown in FIG. 5, and when viewed from the third direction (e.g., the z axis direction), at least portion of the sub-region SR may overlap the main region MR. Although it is shown in FIG. 5 that the display device 10 is bent, embodiments are not limited thereto. As an example, the display device 10 may be a foldable display panel, and in this case, the display device 10 may be bent in the display area DA around a bending axis crossing the display area DA. When needed, the display device 10 may not be bent. The sub-region SR may be a non-display area.

The data driver 20 may be disposed in the sub-region BR of the display device 10. The data driver 20 may be disposed in the form of an integrated circuit (IC) on the display device 10. As an example, the data driver 20 may be a data driving integrated circuit generating data signals.

The display circuit board 30 may be attached to the end of the sub-region SR of the display device 10. The display circuit board 30 may be electrically connected to the data driver 20 or the like through a pad of the sub-region SR of the display device 10.

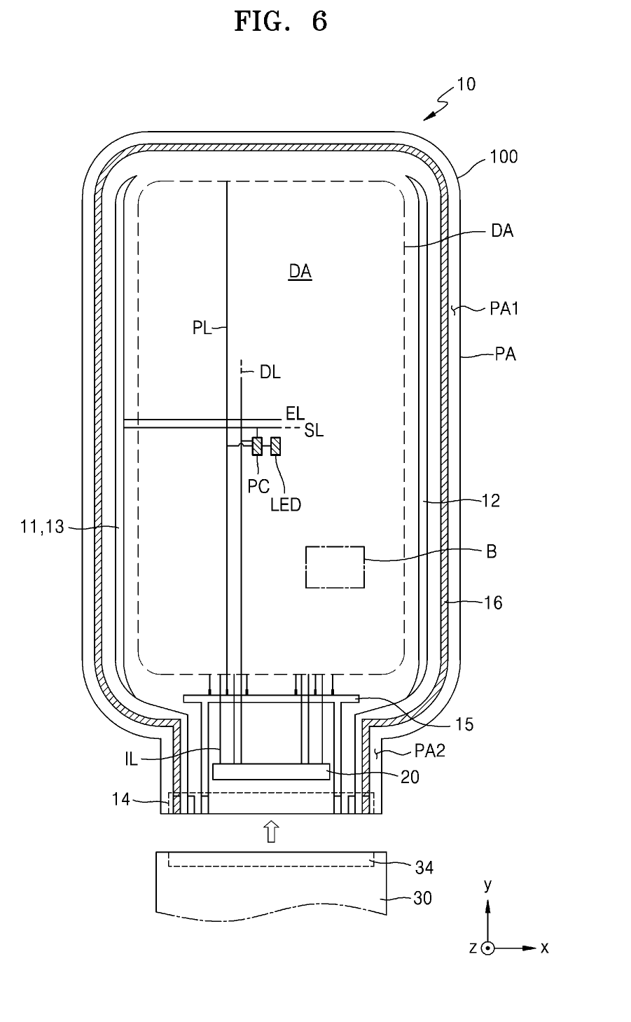

FIG. 6 is a schematic plan view of the display device 10 of FIG. 4. Referring to FIG. 6, the display device 10 may include the substrate 100. Various types of elements forming the display device 10 may be disposed on the substrate 100.

The substrate 100 may include glass, ceramic, metal, or polymer resin. The substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers including the above-described polymer resin, and an inorganic material layer disposed therebetween. Alternatively, the substrate 100 may have a structure in which a layer including the polymer resin and an inorganic material layer are alternately stacked. The inorganic material layer may include silicon oxide, silicon nitride, or silicon oxynitride.

The pixels may be disposed in the display area DA, and the display area DA may display images using light emitted from the pixels. Each pixel may include a light-emitting diode LED, and the light-emitting diode LED may be electrically connected to a sub-pixel circuit PC. The sub-pixel circuit PC and the light-emitting diode LED may be disposed in the display area DA. For convenience, although it is shown in FIG. 6 that the sub-pixel circuit PC and the light-emitting diode LED are located side-by-side, the sub-pixel circuit PC may actually at least partially overlap the light-emitting diode LED. As an example, the light-emitting diode LED may be disposed on the sub-pixel circuit PC.

A gate driving circuit, a pad 14, a first power supply line 15, and a second power supply line 16 may be disposed in the peripheral area PA. The gate driving circuit may include, for example, a first scan driving circuit 11, a second scan driving circuit 12, and/or an emission control driving circuit 13.

The first scan driving circuit 11 may be configured to provide scan signals to the sub-pixel circuit PC through a scan line SL. The second scan driving circuit 12 may be disposed opposite the first scan driving circuit 11 with the display area DA therebetween. Some of the sub-pixel circuits PC disposed in the display area DA may be electrically connected to the first scan driving circuit 11, and the others may be connected to the second scan driving circuit 12. Depending on cases, the second scan driving circuit 12 may be omitted.

Like the first scan driving circuit 11, the emission control driving circuit 13 may be disposed on one side of the display area DA. The emission control driving circuit 13 may provide emission control signals to a pixel P through an emission control line EL. Although it is shown in FIG. 6 that the emission control driving circuit 13 is disposed on only one side of the display area DA, embodiments are not limited thereto. For example, the display device 10 may include the emission control driving circuits 13 disposed on one side and the other side of the display area DA. Alternatively, the first scan driving circuit 11 may be disposed on one side of the display area DA, and the emission control driving circuit 13 may be disposed on the other side of the display area DA.

The pad 14 may be disposed in the second peripheral area PA2 of the substrate 100. The pad 14 may be exposed by not being covered by an insulating layer, and may be electrically connected to the display circuit board 30. A pad 34 of the display circuit board 30 may be electrically connected to the pad 14 of the display device 10.

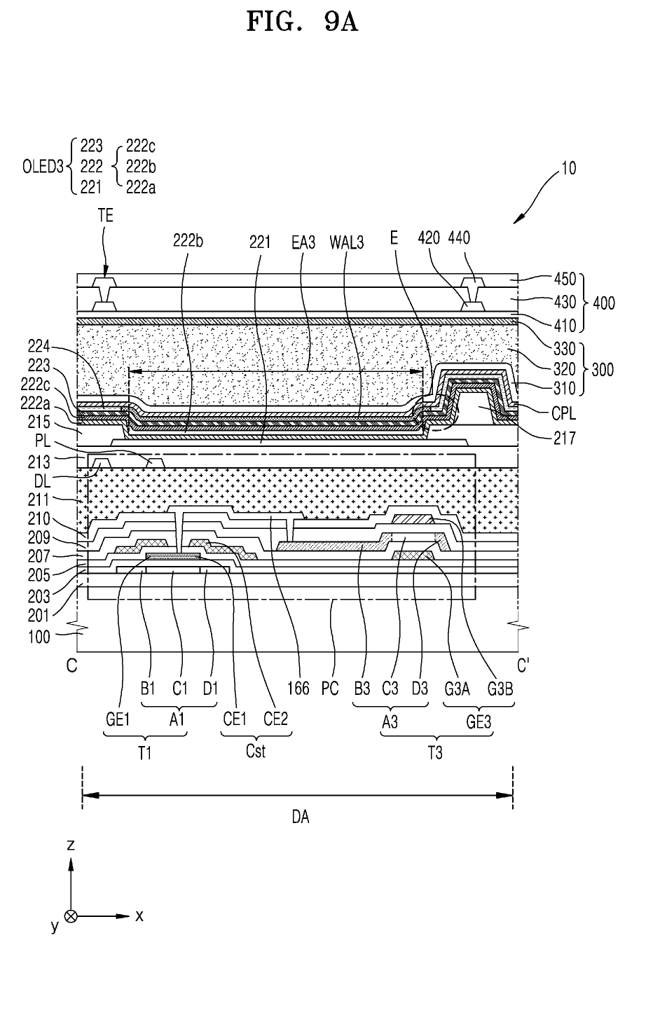

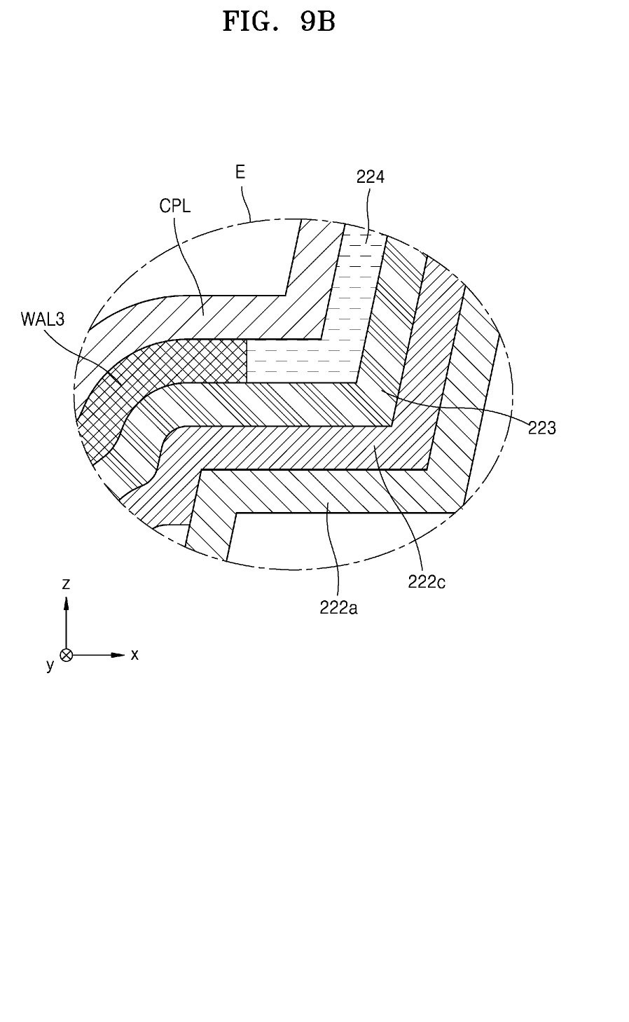

The display circuit board 30 is configured to transfer signals of a controller or power to the display device 10. Control signals generated by the controller may be transferred to the gate driving circuit through the display circuit board 30. In addition, the controller may provide a first power voltage ELVDD and a second power voltage ELVSS to the first power supply line 15 and the second power supply line 16, respectively. The first power voltage ELVDD (referred to as a driving voltage, hereinafter) may be provided to each sub-pixel circuit PC through a driving voltage line PL connected to the first power supply line 15, and the second power voltage ELVSS (referred to as a common voltage, hereinafter) may be provided to a common electrode (e.g., a second electrode 223 in FIG. 9A) of the light-emitting diode LED connected to the second power supply line 16. The first power supply line 15 may extend in the first direction (the x axis direction). The second power supply line 16 may have a loop shape having one open side to partially surround the display area DA.

Data signals of the data driver 20 may be transferred to the sub-pixel circuit PC through the data line DL electrically connected to an input line IL through the input line IL.

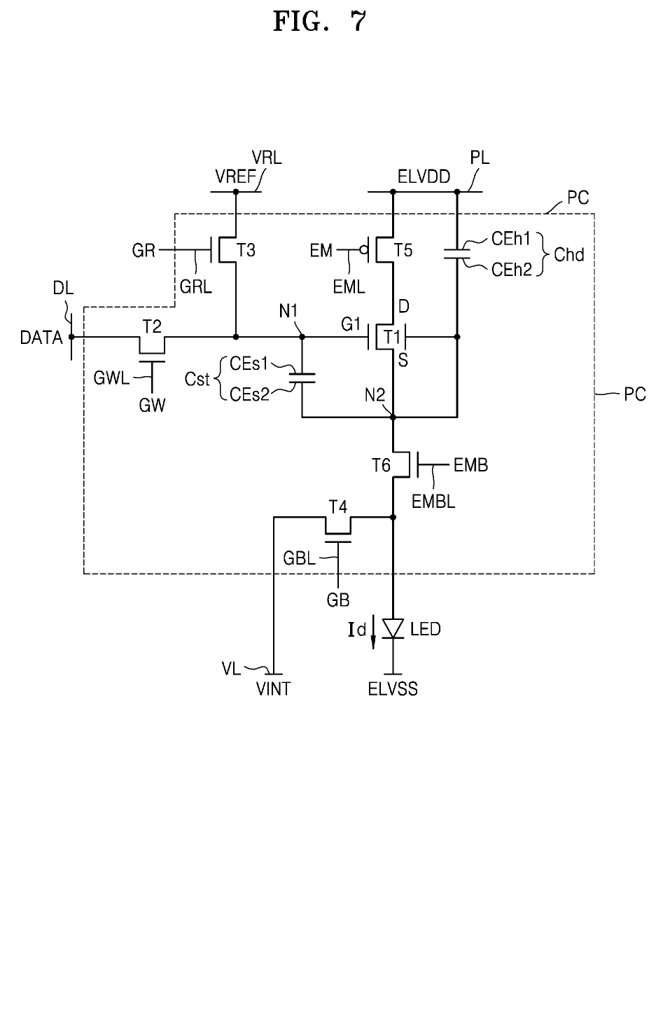

FIG. 7 is an equivalent circuit diagram of the sub-pixel disposed in the display area of the display device of FIG. 4.

Referring to FIG. 7, the light-emitting diode LED is electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 is a switching thin-film transistor, may be connected to the scan line SL and the data line DL, and configured to transfer a data voltage (or a data signal Dm) to the first thin-film transistor T1 based on a switching voltage (or a switching signal Sn), the data voltage being input from the data line DL, and the switching voltage being input from the scan line SL. The storage capacitor Cst may be connected to the second thin-film transistor T2 and the driving voltage line PL and configured to store a voltage corresponding to a difference between a voltage transferred from the second thin-film transistor T2 and the first power voltage ELVDD supplied to the driving voltage line PL.

The first thin-film transistor T1 is a driving thin-film transistor, may be connected to the driving voltage line PL and the storage capacitor Cst, and configured to control a driving current according to the voltage stored in the storage capacitor Cst, the driving current flowing from the driving voltage line PL to the light-emitting diode LED. The light-emitting diode LED may be configured to emit light having a preset brightness corresponding to the driving current. A second electrode (e.g., a cathode) of the light-emitting diode LED may receive the second power voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a drain electrode (or a source electrode) of the first thin-film transistor T1 and be connected to a first electrode of the light-emitting diode LED through the sixth thin-film transistor T6. A drain electrode (or a source electrode) of the third thin-film transistor T3 may be connected to one of electrodes of the storage capacitor Cst, a source electrode (or a drain electrode) of the fourth thin-film transistor T4, and a gate electrode of the first thin-film transistor T1. The third thin-film transistor T3 is turned on according to a scan signal Sn received through the scan line SL and diode-connect the first thin-film transistor T1 by connecting the gate electrode and the drain electrode of the first thin-film transistor T1 to each other.

The fourth thin-film transistor T4 is an initialization thin-film transistor, and a gate electrode of the fourth thin-film transistor T4 may be connected to a previous scan line SL-1. A drain electrode (or a source electrode) of the fourth thin-film transistor T4 may be connected to an initialization voltage line VL. A source electrode (or a drain electrode) of the fourth thin-film transistor T4 may be connected to one of the electrodes of the storage capacitor Cst, a drain electrode (or a source electrode) of the third thin-film transistor T3, and the gate electrode of the first thin-film transistor T1. The fourth thin-film transistor T4 may be turned on according to a previous scan signal Sn-1 received through the previous scan line SL-1 and may perform an initialization operation of initializing the voltage of the gate electrode of the first thin-film transistor T1 by transferring an initialization voltage Vint to the gate electrode of the first thin-film transistor T1.

The fifth thin-film transistor T5 is an operation control thin-film transistor, and a gate electrode of the fifth thin-film transistor T5 may be connected to the emission control line EL. A source electrode (or a drain electrode) of the fifth thin-film transistor T5 may be connected to the driving voltage line PL. A drain electrode (or a source electrode) of the fifth thin-film transistor T5 is connected to the source electrode (or the drain electrode) of the first thin-film transistor T1 and the drain electrode (or the source electrode) of the second thin-film transistor T2.

The sixth thin-film transistor T6 is an emission control thin-film transistor, and a gate electrode of the sixth thin-film transistor T6 may be connected to the emission control line EL. A source electrode (or a drain electrode) of the sixth thin-film transistor T6 is connected to the drain electrode (or the source electrode) of the first thin-film transistor T1 and the source electrode (the drain electrode) of the third thin-film transistor T3. A drain electrode (or a source electrode) of the sixth thin-film transistor T6 may be electrically connected to the first electrode of the light-emitting diode LED. The fifth thin-film transistor T5 and the sixth thin-film transistor T6 may be simultaneously turned on according to an emission control signal En transferred through the emission control line EL, the first power voltage ELVDD is transferred to the light-emitting diode LED, and the driving current flows through the light-emitting diode LED.

The seventh thin-film transistor T7 may be an initialization thin-film transistor configured to initialize the first electrode of the light-emitting diode LED. A gate electrode of the seventh thin-film transistor T7 may be connected to a next scan line SL+1. A source electrode (or a drain electrode) of the seventh thin-film transistor T7 may be connected to the first electrode of the light-emitting diode LED. A drain electrode (or a source electrode) of the seventh thin-film transistor T7 may be connected to the initialization voltage line VL. The seventh thin-film transistor T7 may be turned on according to a next scan signal Sn+1 transferred through the next scan line SL+1 and may initialize the first electrode of the light-emitting diode LED.

Although it is shown in FIG. 7 that the fourth thin-film transistor T4 and the seventh thin-film transistor T7 are respectively connected to the previous scan line SL-1 and the next scan line SL+1, both the fourth thin-film transistor T4 and the seventh thin-film transistor T7 may be connected to the previous scan line SL-1 and driven according to a previous scan signal Sn-1 in another embodiment.

The other electrode of the storage capacitor Cst may be connected to the driving voltage line PL. One of the electrodes of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4 together.

The second electrode (e.g., a cathode) of the light-emitting diode LED is configured to receive the second power voltage ELVSS. The light-emitting diode LED is configured to emit light by receiving the driving current from the first thin-film transistor T1.

The light-emitting diode LED may be an organic light-emitting diode including an organic material as an emission material. In another embodiment, the light-emitting diode may be an inorganic light-emitting diode including an inorganic material. The inorganic light-emitting diode may include a PN diode including inorganic material semiconductor-based materials. When a forward voltage is applied to a PN-junction diode, holes and electrons are injected, and light of a preset color may be emitted while energy released by recombination of the holes and the electrons is converted to light energy. The inorganic light-emitting diode may have a width of several micrometers to hundreds of micrometers, or several nanometers to hundreds of nanometers. In an embodiment, the light-emitting diode LED may be a quantum-dot light-emitting diode. As described above, an emission layer of the light-emitting diode LED may include an organic material, an inorganic material, quantum dots, an organic material and quantum dots, or inorganic material and quantum dots. Hereinafter, for convenience of description, the case where the light-emitting diode LED includes an organic light-emitting diode is described.

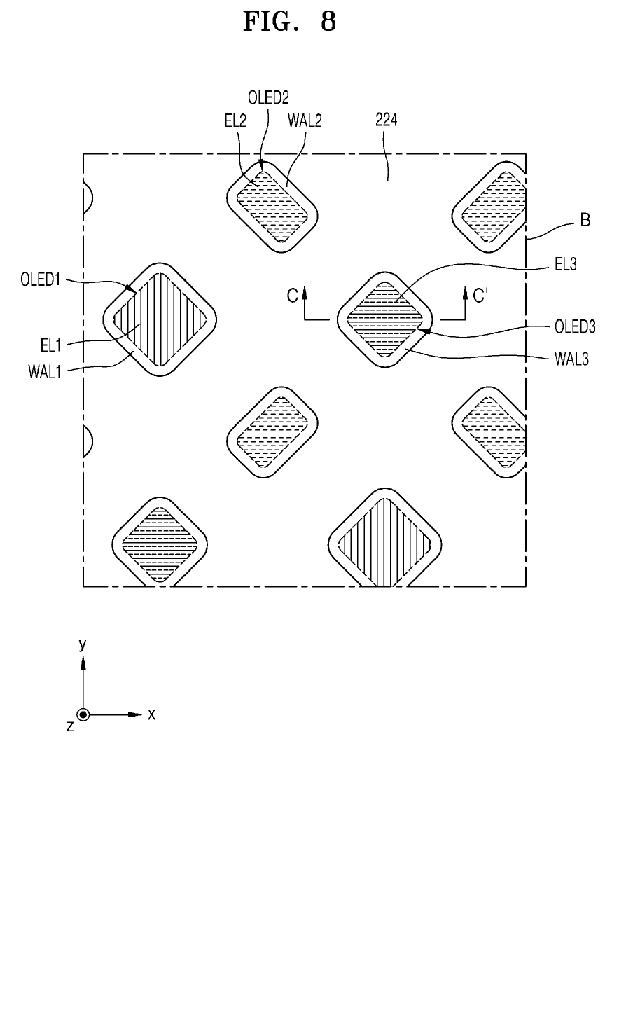

FIG. 8 is a schematic enlarged plan view of a region B of FIG. 6. FIG. 9A is a schematic cross-sectional view taken along line C-C’ of FIG. 8. FIG. 9B is a schematic enlarged cross-sectional view of a region E of FIG. 9A. FIG. 9A shows the sub-pixel circuit PC and the light-emitting diode, for example, the organic light-emitting diode OLED disposed in the display area DA of the display device.

Referring to FIGS. 8 to 9B, a plurality of sub-pixels including the sub-pixel circuit PC and the light-emitting diode may be disposed in the display area DA. In this case, the plurality of sub-pixels may emit light of different colors. In this case, a light-emitting diode included in each sub-pixel may include an organic light-emitting diode. The organic light-emitting diodes may include a first organic light-emitting diode OLED1, a second organic light-emitting diode OLED2, and a third organic light-emitting diode OLED3 emitting light of different colors. In this case, one of the first organic light-emitting diode OLED1, the second organic light-emitting diode OLED2, and the third organic light-emitting diode OLED3 may emit one of red, green, or blue light. Another of the first organic light-emitting diode OLED1, the second organic light-emitting diode OLED2, and the third organic light-emitting diode OLED3 may emit another of red, green, and blue light. Still another of the first organic light-emitting diode OLED1, the second organic light-emitting diode OLED2, and the third organic light-emitting diode OLED3 may emit still another of red, green, and blue light. Hereinafter, for convenience of description, a case where the first organic light-emitting diode OLED1 emits blue light, the second organic light-emitting diode OLED2 emits green light, and the third organic light-emitting diode OLED3 emits red light is mainly described in detail.

In this case, the first organic light-emitting diode OLED1 and the third organic light-emitting diode OLED3 may be disposed apart from each other in the first direction and/or second direction. In this case, the first organic light-emitting diode OLED1 and the third organic light-emitting diode OLED3 may be alternately disposed in the first direction and/or second direction. In addition, the second organic light-emitting diode OLED2 may be disposed to face the first organic light-emitting diode OLED1 and the third organic light-emitting diode OLED3. In this case, four second organic light-emitting diodes OLED2 may face one first organic light-emitting diode OLED1 and one third organic light-emitting diode OLED3.

A protective layer may be disposed on each light-emitting diode. As an example, a first protective layer WAL1 may be disposed on a first emission area EA1 of the first organic light-emitting diode OLED1, a second protective layer WAL2 may be disposed on a second emission area EA2 of the second organic light-emitting diode OLED2, and a third protective layer WAL3 may be disposed on a third emission area EA3 of the third organic light-emitting diode OLED3.

In this case, the first protective layer WAL1 may be disposed to overlap the first emission area EA1 in a plan view. In this case, a planar shape of the first emission area EA1 may be disposed within a planar shape of the first protective layer WAL1. In another embodiment, the planar-shaped border of the first protective layer WAL1 and the planar-shaped border of the first emission area EA1 may coincide with each other.

The first protective layer WAL1, the second protective layer WAL2, and the third protective layer WAL3 may be disposed apart from one another. In this case, the first protective layer WAL1 may have an island shape. That is, the first protective layer WAL1 may be disposed apart from another first protective layer WAL1 and disposed apart from the second protective layer WAL2 and the third protective layer WAL3. In this case, the planar shape of the first protective layer WAL1 may be various. In an embodiment, the planar shape of the first protective layer WAL1 may be a polygon, a circle, or an ellipse. In another embodiment, the planar shape of the first protective layer WAL1 may be an irregular shape other than a polygon, a circle, and an ellipse. In this case, a planar shape of the first emission area EA1 may be disposed within a planar shape of the first protective layer WAL1. The second protective layer WAL2 and the third protective layer WAL3 may have a similar shape to the first protective layer WAL1. In addition, a relationship between the first protective layer WAL1 and the first emission layer EA1 is applicable to both a relationship between the second protective layer WAL2 and the second emission layer EA2, and a relationship between the third protective layer WAL3 and the third emission layer EA3. Hereinafter, for convenience of description, the display area of the display device in which the third organic light-emitting diode OLED3 and the third protective layer WAL3 are disposed, is described in detail.

The substrate 100 may include glass, ceramic, metal, or polymer resin. In an embodiment, the substrate 100 may have a stack structure in which a base layer including polymer resin and a barrier layer including an inorganic insulating material such as silicon oxide or silicon nitride are alternately stacked. Because, in the case where the substrate 100 includes a stack structure including the base layer of the polymer resin and the barrier layer of the inorganic insulating material, flexibility of the electronic apparatus 1 is improved, a foldable electronic apparatus 1 may be provided.

The inorganic insulating material may include silicon oxide, silicon nitride, or silicon oxynitride.

The polymer may include polyethersulphone, polyacrylate, polyetherimide, polyethylene naphthalate, polyethylene terephthalate, polyphenylene sulfide, polyarylate, polyimide, polycarbonate, and/or cellulose acetate propionate. Hereinafter, for convenience of description, a case where the substrate 100 includes a glass material is described in detail.

The sub-pixel circuit PC may be formed on the substrate 100, and the light-emitting diode, for example, the third organic light-emitting diode OLED3 may be formed on the sub-pixel circuit PC.

A buffer layer 201 may be formed on the substrate 100 before the sub-pixel circuit PC is formed on the substrate 100 to prevent impurities from penetrating the sub-pixel circuit PC. The buffer layer 201 may include an inorganic insulating material such as silicon nitride, silicon oxynitride, and/or silicon oxide, and may include a single-layered structure or a multi-layered structure including one or more of the above inorganic insulating materials.

As described above with reference to FIG. 7, the sub-pixel circuit PC may include the plurality of transistors and the storage capacitor. With regard to this, FIG. 9A shows the first thin-film transistor T1, the third thin-film transistor T3, and the storage capacitor Cst.

The first thin-film transistor T1 may include a semiconductor layer (referred to as a first semiconductor layer A1) on the buffer layer 201, and a gate electrode (referred to as a first gate electrode GE1) overlapping a channel region C1 of the first semiconductor layer A1. The first semiconductor layer A1 may include a silicon-based semiconductor material, for example, polycrystalline silicon. The first semiconductor layer A1 may include the channel region C1, a first region B1, and a second region D1 respectively disposed on two opposite sides of the channel region C1. The channel region C1 may be provided between the first region B1 and the second region D1. The first region B1 and the second region D1 are regions including impurities of higher concentration than that of the channel region C1. One of the first region B1 and the second region D1 may correspond to a source region, and the other may correspond to a drain region.

A first gate insulating layer 203 may be disposed between the first semiconductor layer A1 and the first gate electrode GE1. The first gate insulating layer 203 may include an inorganic insulating material such as silicon nitride, silicon oxynitride, and silicon oxide, and may include a single-layered structure or a multi-layered structure including one or more of the above inorganic insulating materials.

The first gate electrode GE1 may include a conductive material including molybdenum (Mo), aluminum (Al), copper (Cu), and/or titanium (Ti) and may have a single-layered structure or a multi-layered structure including one or more of the above materials.

The storage capacitor Cst may include a lower electrode CE1 and an upper electrode CE2 overlapping each other. In an embodiment, the lower electrode CE1 of the storage capacitor Cst may include the first gate electrode GE1. In this regard, the first gate electrode GE1 may include the lower electrode CE1 of the storage capacitor Cst. As an example, the first gate electrode GE1 and the lower electrode CE1 of the storage capacitor Cst may be integrally formed.

A first interlayer insulating layer 205 may be disposed between the lower electrode CE1 and the upper electrode CE2 of the storage capacitor Cst. The first interlayer insulating layer 205 may include an inorganic insulating material such as silicon oxide, silicon nitride, and/or silicon oxynitride, and may include a single-layered structure or a multi-layered structure including one or more of the above inorganic insulating materials.

The upper electrode CE2 of the storage capacitor Cst may include a conductive material of a low-resistance material such as molybdenum (Mo), aluminum (Al), copper (Cu) and/or titanium (Ti), and may have a single-layered structure or a multi-layered structure including one or more of the above materials.

A second interlayer insulating layer 207 may be disposed on the storage capacitor Cst. The second interlayer insulating layer 207 may include an inorganic insulating material such as silicon oxide, silicon nitride, and/or silicon oxynitride, and may include a single-layered structure or a multi-layered structure including one or more of the above inorganic insulating materials.

A semiconductor layer (referred to as a third semiconductor layer A3, hereinafter) of the third thin-film transistor T3 may be disposed on the second interlayer insulating layer 207. The third semiconductor layer A3 may include an oxide-based semiconductor material. As an example, the third semiconductor layer A3 may include Zn-oxide-based material, for example, Zn-oxide, In-Zn oxide, and/or Ga-In-Zn oxide. In an embodiment, the third semiconductor layer A3 may include In-Ga-Zn-O (IGZO), In-Sn-Zn-O (ITZO), and/or In-Ga-Sn-Zn-O (IGTZO) semiconductor containing metal such as indium (In), gallium (Ga), and stannum (Sn) in ZnO.

The third semiconductor layer A3 may include a channel region C3, a first region B3, and a second region D3 respectively disposed on two opposite sides of the channel region C3. One of the first region B3 and the second region D3 may correspond to a source region, and the other may correspond to a drain region.

The third thin-film transistor T3 may include a gate electrode (referred to as a third gate electrode GE3, hereinafter) overlapping the channel region C3 of the third semiconductor layer A3. The third gate electrode GE3 may have a double gate structure including a lower gate electrode G3A and an upper gate electrode G3B, wherein the lower gate electrode G3A is below the third semiconductor layer A3, and the upper gate electrode G3B is over the channel region C3.

The lower gate electrode G3A may be disposed on the same layer (e.g., the first interlayer insulating layer 205) as the upper electrode CE2 of the storage capacitor Cst. The lower gate electrode G3A may include the same material as a material of the upper electrode CE2 of the storage capacitor Cst.

The upper gate electrode G3B may be disposed over the third semiconductor layer A3 with a second gate insulating layer 209 therebetween. The second gate insulating layer 209 may include an inorganic insulating material such as silicon oxide, silicon nitride, and/or silicon oxynitride, and may include a single-layered structure or a multi-layered structure including one or more of the above inorganic insulating materials.

A third interlayer insulating layer 210 may be disposed on the upper gate electrode G3B. The third interlayer insulating layer 210 may include an inorganic insulating material such as silicon oxynitride, and may have a single layer or a multi-layer including the inorganic insulating materials.

Although FIG. 9A shows the first thin-film transistor T1 and the third thin-film transistor T3 among the plurality of thin-film transistors and the first semiconductor layer A1 and the third semiconductor layer A3 are disposed on different layers as described with reference to FIG. 7, embodiments are not limited thereto.

The second, fifth, sixth, and seventh thin-film transistors T2, T5, T6, and T7 described with reference to FIG. 7 may have the same structure as the first thin-film transistor T1 described with reference to FIG. 9A. As an example, the second, fifth, sixth, and seventh thin-film transistors T2, T5, T6, and T7 may include a semiconductor layer disposed on the same layer as the first semiconductor layer A1 of the first thin-film transistor T1, and a gate electrode disposed on the same layer as the first gate electrode GE1 of the first thin-film transistor T1. The semiconductor layers of the second, fifth, sixth, and seventh thin-film transistors T2, T5, T6, and T7 may be integrally connected to the first semiconductor layer A1.

The fourth thin-film transistor T4 described with reference to FIG. 7 may have the same structure as that of the third thin-film transistor T3 described with reference to FIG. 9A. As an example, the fourth thin-film transistor T4 may include a semiconductor layer disposed on the same layer as the third semiconductor layer A3 of the third thin-film transistor T3, and a gate electrode formed on the same layer as the third gate electrode GE3 of the third thin-film transistor T3. A semiconductor layer of the fourth thin-film transistor T4 may be integrally connected to the third semiconductor layer A3 of the third thin-film transistor T3.

The first thin-film transistor T1 may be electrically connected to the third thin-film transistor T3 through a node connection line 166. The node connection line 166 may be disposed on the third interlayer insulating layer 210. One side of the node connection line 166 may be connected to the first gate electrode GE1 of the first thin-film transistor T1, and another side of the node connection line 166 may be connected to the third semiconductor layer A3 of the third thin-film transistor T3.

The node connection line 166 may include aluminum (Al), copper (Cu), and/or titanium (Ti), and may include a single layer or a multi-layer including one or more of the above materials. As an example, the node connection line 166 may have a three-layered structure of a titanium layer, an aluminum layer and a titanium layer, and the aluminum layer may be provided between the two titanium layers.

A first organic insulating layer 211 may be disposed on the node connection line 166. The first organic insulating layer 211 may include an organic insulating material. The organic insulating material may include acryl, benzocyclobutene (BCB), polyimide, and/or hexamethyldisiloxane (HMDSO).

The data line DL and the driving voltage line PL may be disposed on the first organic insulating layer 211 and covered by a second organic insulating layer 213. The data line DL and the driving voltage line PL may include aluminum (Al), copper (Cu), and/or titanium (Ti), and may include a single layer or a multi-layer including one or more of the above materials. As an example, the data line DL and the driving voltage line PL may each have a triple-layered structure of a titanium layer, an aluminum layer and a titanium layer, and the aluminum layer may be provided between the two titanium layers.

The second organic insulating layer 213 may include acryl, BCB, polyimide, and/or HMDSO. Although it is shown in FIG. 9A that the data line DL and the driving voltage line PL are disposed on the first organic insulating layer 211, embodiments are not limited thereto. In another embodiment, one of the data line DL and the driving voltage line PL may be disposed on the same layer (e.g., the third interlayer insulating layer 210) as the node connection line 166.

A light-emitting diode, for example, the third organic light-emitting diode OLED3 may be disposed on the second organic insulating layer 213.

A first electrode 221 of the third organic light-emitting diode OLED3 may include a reflective layer including silver (Ag), magnesium (Mg), aluminum (Al), platinum (Pt), palladium (Pd), gold (Au), nickel (Ni), neodymium (Nd), iridium (Ir), chrome (Cr), and/or a compound thereof. In another embodiment, the first electrode 221 may further include a conductive oxide material layer on and/or under the reflective layer. The conductive oxide material layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the first electrode 221 may have a three-layered structure of an ITO layer, an Ag layer and an ITO layer, and the Ag layer may be provided between the two ITO layers.

The first electrodes 221 may be disposed apart from each other to respectively correspond to the organic light-emitting diodes. In this case, the planar shapes and/or sizes of the first electrodes 221 may be different from each other depending on the emission areas of the respectively organic light-emitting diodes.

A bank layer 215 may be disposed on the first electrode 221. The bank layer 215 may include (i.e., define) an opening that overlaps the first electrode 221 and cover the edge of the first electrode 221. The bank layer 215 may include an organic insulating material such as polyimide. In this case, the opening of the bank layer 215 may expose a portion of the first electrode 221 to the outside. In this case, a portion of the first electrode 221 exposed through the bank layer 215 may be defined as a third emission area EA3.

A third intermediate layer 222 includes a third emission layer 222b. The third intermediate layer 222 may include a first functional layer 222a and/or a second functional layer 222c, wherein the first functional layer 222a is under the third emission layer 222b, and the second functional layer 222c is on the third emission layer 222b. The third emission layer 222b may include a polymer organic material or a low-molecular weight organic material configured to emit light having a preset color. The second functional layer 222c may include an electron transport layer (ETL) and/or an electron injection layer (EIL). The first functional layer 222a and the second functional layer 222c may each include an organic material.

The first organic light-emitting diode OLED1 may include a first intermediate layer, and the second organic light-emitting diode OLED2 may include a second intermediate layer. In this case, the first intermediate layer may include a first emission layer, and the second intermediate layer may include a second emission layer. The first emission layer, the second emission layer, and the third emission layer 222b may include different materials emitting light of different colors when voltages are applied.

A second electrode 223 may include a conductive material having a low work function. As an example, the second electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), and/or an alloy thereof. Alternatively, the second electrode 223 may further include a layer on the (semi) transparent layer, the layer including ITO, IZO, ZnO, and/or In₂O₃.

The third emission layer 222b may be formed in the display area DA to overlap the first electrode 221 through the opening of the bank layer 215. In contrast, the first functional layer 222a, the second functional layer 222c, and the second electrode 223 may cover the display area DA entirely.

The third protective layer WAL3 and an auxiliary electrode 224 may be disposed on the second electrode 223. In this case, the third protective layer WAL3 may include various materials. As an example, the third protective layer (WAL3) may be formed using substances which are weak adhesion layers such as 8-quinolinatolithium (Liq; [8-Quinolinolato Lithium]), N,N-diphenyl-N,N-bis(9-phenyl-9H-carbazol-3-yl)biphenyl-4,4’-diamine (HT01), N(diphenyl-4-yl)9,9-dimethyl-N-(4(9-phenyl-9H-carbazol-3-yl)phenyl)-9H-fluorene-2-amine (HT211)) and/or 2-(4-(9,10-di(naphthalene-2-yl)anthracene-2-yl)phenyl)-1-phenyl-1H-benzo-[D]imidazole (2-(4-(9,10-di(naphthalene-2-yl)anthracene-2-yl)phenyl)-1-phenyl-1H-benzo-[D]imidazole; LG201). The third protective layer WAL3 may shield the third emission area EA3 entirely. For example, the third protective layer WAL3 may overlap all of the third emission area EA3 in a plan view. In addition, the third protective layer WAL3 may include a host of an organic emission layer and/or a capping layer CPL. In the case where the third protective layer WAL3 includes the capping layer CPL, the third protective layer WAL3 may be an organic material having a higher refractive index than the second electrode 223. In addition, in the case where the third protective layer WAL3 includes the capping layer CPL, the third protective layer WAL3 may include layers of different refractive indexes stacked therein. As an example, the third protective layer WAL3 may include a high refractive index layer, a low refractive index layer and a high refractive index layer that are stacked, and the low refractive index layer may be provided between the two high refractive index layers. In this case, the refractive index of the high refractive index layer may be 1.7 or more, and the refractive index of the low refractive index layer may be 1.3 or less. The third protective layer WAL3 may additionally include lithium fluoride (LiF). Alternatively, the third protective layer WAL3 may additionally include an inorganic insulating material such as silicon oxide (SiO₂) and/or silicon nitride (SiNₓ).

The third protective layer WAL3 may include a material having a low interface adhesive force with respect to a material used as the auxiliary electrode 224. In this case, the auxiliary electrode 224 may not be deposited on the upper surface of the third protective layer WAL3, or the auxiliary electrode 224 may be only deposited on a very small portion of the third protective layer WAL3. Through this, the auxiliary electrode 224 may not be disposed on the upper surface of the third protective layer WAL3. Accordingly, because the auxiliary electrode 224 is not disposed in the third emission area EA3 (i.e., is offset from the third emission area EA3) in which the third protective layer WAL3 is disposed, optical characteristics of the third organic light-emitting diode OLED3 may not be variable. In this regard, optical characteristics may be consistent an thereby provide improved image quality. In this case, an adhesive force between the third protective layer WAL3 and the auxiliary electrode 224 indicates surface energy of a solid, and may determine a behavior after the solid is in contact with a different material. As an example, when a material having low surface energy is provided to a solid having high surface energy, deposition on the solid may be difficult due to a difference in surface energy. The surface energy may be measured using an optical tensiometer, and calculated by applying, to a Lewis Acid/Base model, a contact angle obtained by providing liquid drops of pure water, pure diiodomethane, and pure ethylene glycol respectively to a solid surface.

The auxiliary electrode 224 may include a metal, alloy, metal nitride, conductive metal oxide, and/or transparent conductive material having high adhesive force to the second electrode 223. In the auxiliary electrode 224, these materials may be used alone or in combination with each other. As an example, the auxiliary electrode 224 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), and/or a mixture thereof (e.g., AgMg), an alloy thereof. Alternatively, the auxiliary electrode 224 may further include a reflective layer, the (semi) transparent layer, and/or a layer on the (semi) transparent layer, the layer including ITO, IZO, ZnO, AZO, or In₂O₃. In this case, the auxiliary electrode 224 and the second electrode 223 may be different materials or the same material. Particularly, in the case where the auxiliary electrode 224 and the second electrode 223 are different materials, bonding force between the third protective layer WAL3 and the auxiliary electrode 224 may be greater than bonding force between the second electrode 223 and the third protective layer WAL3.

In this case, surface energy of the auxiliary electrode 224 is similar to or greater than surface energy of the second electrode 223, and in the case where surface energy of the third protective layer WAL3 is less than surface energy of the second electrode 223, when the third protective layer WAL3 is disposed on the second electrode 223 and then the auxiliary electrode 224 is disposed on the third protective layer WAL3 and the second electrode 223, a contact angle increases due to a difference in surface energy, and accordingly, the auxiliary electrode 224 may not be disposed on the third protective layer WAL3. Accordingly, the auxiliary electrode 224 may be disposed not to overlap the third emission area EA3. Particularly, because the auxiliary electrode 224 is not present in the third emission area EA3 overlapping the third protective layer WAL3 in a plan view, the same pixel emission characteristic as the existing pixel emission characteristic regardless of the auxiliary electrode 224, and an electrical resistance is reduced due to an influence of the additionally deposited auxiliary electrode 224 in a non-emission area, and accordingly, electrical characteristics may be improved. As a result, electrical characteristics such as IR-drop may be improved without an influence on other optical characteristics of the display device 10.

The auxiliary electrode 224 may be disposed around the third emission area EA3. That is, the auxiliary electrode 224 may be disposed in a region where light emission does not occur, and is offset from the third emission area EA3. In this case, the auxiliary electrode 224 may have a mesh structure. The auxiliary electrode 224 may be connected to the second electrode 223. Because the auxiliary electrode 224 is connected to the second electrode 223, the magnitude of an entire resistance may be reduced in a portion of the second electrode 223 in which the auxiliary electrode 224 is disposed. Through this, IR-drop may be reduced.

A spacer 217 may be formed on the bank layer 215. The spacer 217 may be formed together with the bank layer 215 during the same process as a process of forming the bank layer 215, or formed separately during a separate process. In an embodiment, the spacer 217 may include an organic insulating material such as polyimide. Alternatively, the bank layer 215 may include an organic insulating material including a light-blocking dye, and the spacer 217 may include an organic insulating material such as polyimide.

The third organic light-emitting diode OLED3 may be covered by an encapsulation layer 300. The encapsulation layer 300 may include at least one organic encapsulation layer and at least one inorganic encapsulation layer. In an embodiment, it is shown in FIG. 9A that the encapsulation layer 300 includes first and second inorganic encapsulation layers 310 and 330, and an organic encapsulation layer 320 therebetween.

The first and second inorganic encapsulation layers 310 and 330 may include at least one inorganic material among aluminum oxide, titanium oxide, tantalum oxide, hafnium oxide, zinc oxide, silicon oxide, silicon nitride, silicon oxynitride, and the like. The first and second inorganic encapsulation layers 310 and 330 may include a single layer or a multi-layer including one or more of the above materials. The organic encapsulation layer 320 may include a polymer-based material. The polymer-based material may include an acryl-based resin, an epoxy-based resin, polyimide, and/or polyethylene. In an embodiment, the organic encapsulation layer 320 may include acrylate.

The thickness of the first inorganic encapsulation layer 310 may be different from that of the second inorganic encapsulation layer 330. The thickness of the first inorganic encapsulation layer 310 may be greater than that of the second inorganic encapsulation layer 330. Alternatively, the thickness of the second inorganic encapsulation layer 330 may be greater than that of the first inorganic encapsulation layer 310, or the thickness of the first inorganic encapsulation layer 310 may be the same as that of the second inorganic encapsulation layer 330.

An input-sensing layer 400 may be disposed on the encapsulation layer 300. The input-sensing layer 400 may include touch electrodes TE and at least one touch insulating layer disposed in the display area DA. With regard to this, it is shown in FIG. 9A that the input-sensing layer 400 includes a first touch insulating layer 410, a first conductive line 420, a second touch insulating layer 430, a second conductive line 440, and a third touch insulating layer 450, wherein the first touch insulating layer 410 is on the second inorganic encapsulation layer 330, the first conductive line 420 is on the first touch insulating layer 410, the second touch insulating layer 430 is on the first conductive line 420, the second conductive line 440 is on the second touch insulating layer 430, and the third touch insulating layer 450 is on the second conductive line 440.

The first touch insulating layer 410, the second touch insulating layer 430, and the third touch insulating layer 450 may each include an inorganic insulating material and/or an organic insulating material. In an embodiment, the first touch insulating layer 410 and the second touch insulating layer 430 may each include an inorganic insulating material such as silicon oxide, silicon nitride, and/or silicon oxynitride, and the third touch insulating layer 450 may include an organic insulating material.

The touch electrode TE of the input-sensing layer 400 may have a structure in which the first conductive line 420 is connected to the second conductive line 440. Alternatively, the touch electrode TE may include one of the first conductive line 420 and the second conductive line 440. In this case, the second touch insulating layer 430 may be omitted.

Each of the first conductive line 420 and the second conductive line 440 may include aluminum (Al), copper (Cu), and/or titanium (Ti), and may include a single layer or a multi-layer including one or more of the above materials. As an example, each of the first conductive line 420 and the second conductive line 440 may have a triple-layered structure of a titanium layer, an aluminum layer and a titanium layer, and the aluminum layer may be provided between the two titanium layers.

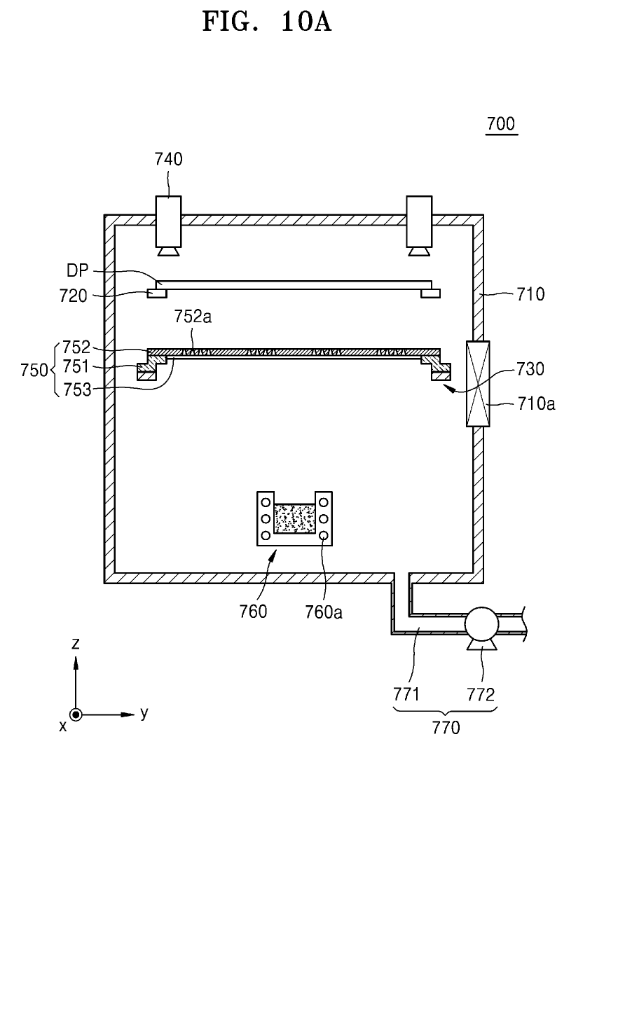

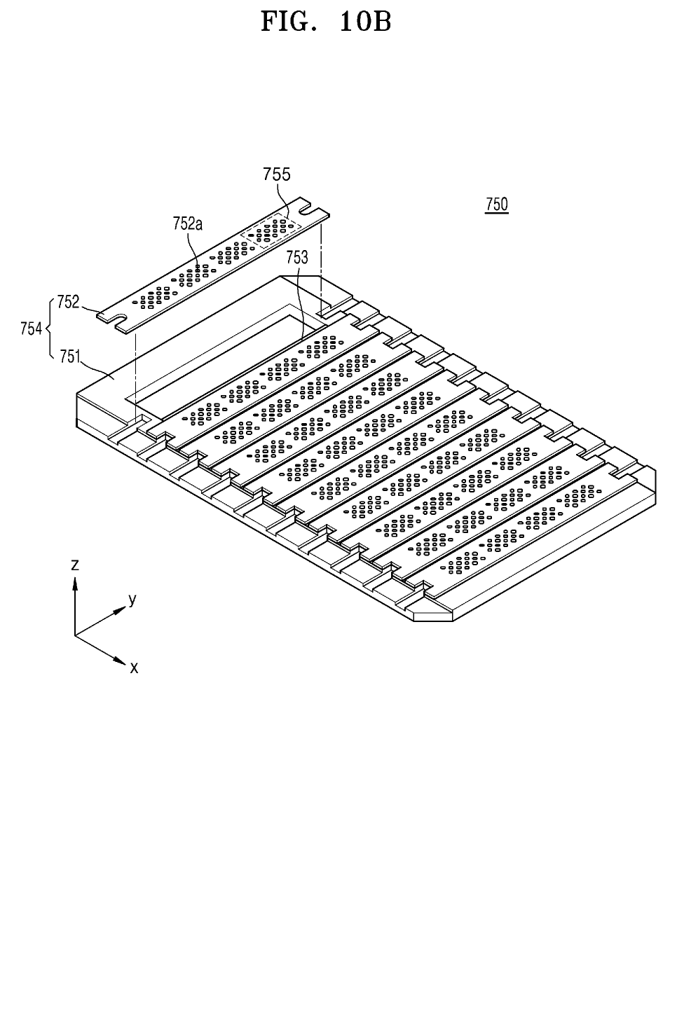

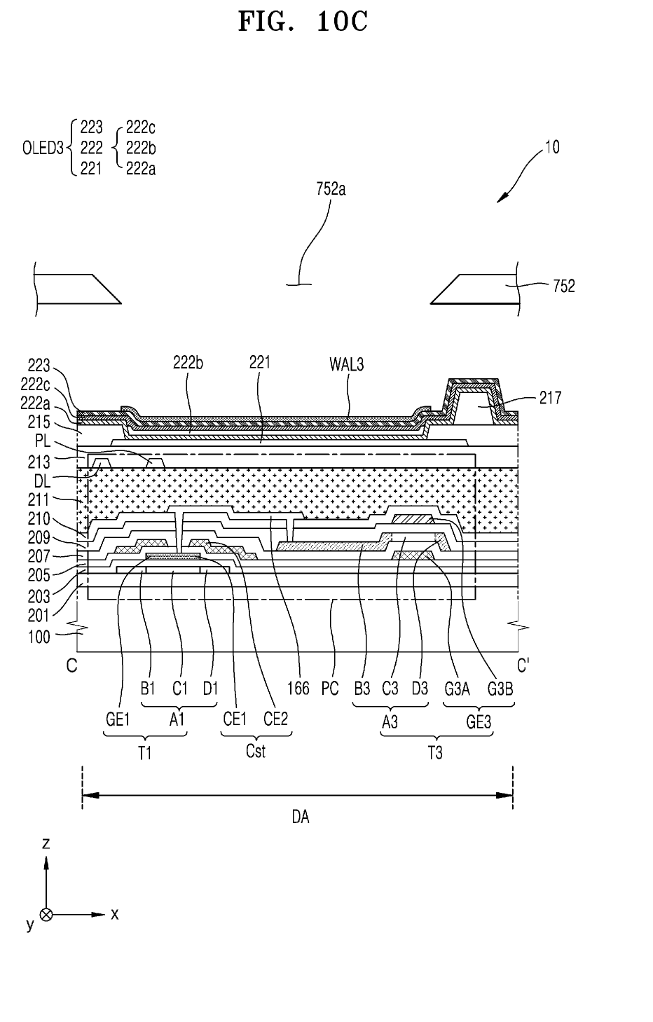

FIG. 10A is a schematic cross-sectional view showing an apparatus for manufacturing a first display device according to an embodiment. FIG. 10B is a schematic perspective view of a first mask assembly shown in FIG. 10A. FIG. 10C is a schematic cross-sectional view showing some of a method of manufacturing a display device according to an embodiment. In FIG. 10C, the same reference numerals as those in FIG. 8 denote the same components.

Referring to FIGS. 10A to 10C, an apparatus 700 for manufacturing the first display device may include a first chamber 710, a first mask assembly 750, a first deposition source 760, a first supporter 720, a second supporter 730, a first suction portion 770, and a first vision portion 740.

The first mask assembly 750 may include a first mask frame 751, a first mask sheet 752, and a first support frame 753.

The first mask assembly 750 may include a first body portion 754 and a first pattern portion 755. The first body portion 754 may include the first mask frame 751 and the first mask sheet 752. In this case, the first mask frame 751 and the first mask sheet 752 may be separately manufactured and coupled to each other. In another embodiment, the first mask frame 751 and the first mask sheet 752 may be integrally manufactured. However, for convenience of description, a case where the first mask frame 751 and the first mask sheet 752 are separately manufactured and coupled to each other is mainly described below in detail.

The first mask frame 751 may include a plurality of frames connected to each other or one frame. In this case, the first mask frame 751 may be formed such that the interior thereof is penetrated. Particularly, the first mask frame 751 may be formed such that the central portion thereof is completely penetrated. The first mask frame 751 may be formed such that the central portion thereof has a grid shape and a portion thereof is penetrated.

The first mask sheet 752 may be disposed on the first mask frame 751. In this case, the first mask sheet 752 may be integrally formed to completely shield one surface of the first mask frame 751. In another embodiment, the first mask sheet 752 may be provided in plurality, and the plurality of first mask sheets 752 may be disposed adjacent to each other on the first mask frame 751 to completely shield one surface of the first mask frame 751. Particularly, the plurality of mask sheets 752 may completely shield an open portion of the first mask frame 751. Hereinafter, for convenience of description, a case where the first mask sheet 752 is provided in plurality is mainly described in detail.

The first pattern portion 755 may be formed in the first mask sheet 752. In this case, at least one first opening 752a may be disposed in (i.e., defined by) the first pattern portion 755. In the case where the first opening 752a is provided in plurality, the plurality of first openings 752a may be disposed apart from each other to form a preset pattern. The first opening 752a disposed in one first mask sheet 752 may be formed to correspond to a planar shape of at least one of the first protective layer WAL1, the second protective layer WAL2, and the third protective layer WAL3 shown in FIG. 8. As an example, in an embodiment, the plurality of first openings 752a may have the same shape as a shape of one of the first protective layer WAL1, the second protective layer WAL2, and the third protective layer WAL3. In this case, three first mask assemblies 750 may be provided, and the first opening 752a of the first mask sheet 752 of one of the three mask assemblies 750 corresponds to the pattern of the first protective layer WAL1. In addition, the first opening 752a of the first mask sheet 752 of another of the three mask assemblies 750 may correspond to the pattern of the second protective layer WAL2, and the first opening 752a of the first mask sheet 752 of still another of the three mask assemblies 750 may correspond to the pattern of the third protective layer WAL3. In this case, in case of forming different protective layers, different mask assemblies may be used. In another embodiment, the plurality of first openings 752a disposed in one first mask sheet 752 may have the same shapes as the shapes of at least two among the first protective layer WAL1, the second protective layer WAL2, and the third protective layer WAL3. In this case, two different first openings among the plurality of first openings 752a may have different planar shapes or different sizes. Hereinafter, for convenience of description, a case where the first openings 752a disposed in one first mask sheet 752 have shapes respectively corresponding to the first protective layer WAL1, the second protective layer WAL2, and the third protective layer WAL3 is mainly described in detail.

At least one first pattern portion 755 may be provided in the first mask sheet 752. In the case where the first mask sheet 752 includes a plurality of first pattern portions 755, the plurality of first pattern portions 755 may be formed apart from each other. The first pattern portion 755 may be formed to correspond to a display area of a display device to be manufactured.

The first mask assembly 750 may include the first support frame 753 disposed on the first mask frame 751. In this case, the first support frame 753 may be disposed to face the first mask sheet 752 and disposed between the adjacent first mask sheets 752. In addition, the first support frame 753 may be disposed in a direction perpendicular to the lengthwise direction of the first mask sheet 752. The first support frame 753 may not only prevent transformation of the first mask frame 751 but also prevent the first mask sheet 752 from sagging due to the weight thereof.

The first chamber 710 may include a space therein and be formed such that a portion thereof is open. In this case, a first gate valve 710a may be disposed in the open portion of the first chamber 710 to selectively open or close the open portion of the first chamber 710.

The first deposition source 760 may accommodate a first raw material that is a protective layer-forming material and a first deposition material inside. In this case, the first raw material is a sublimating or vaporizing material and may include at least one of an inorganic material and an organic material. Hereinafter, for convenience of description, the case where the first raw material includes an organic material is mainly described in detail.

The first deposition source 760 may be disposed to face the first mask frame 751, and a portion of the first deposition source 760 disposed to face the first mask frame 751 may be formed to be open. In addition, the first deposition source 760 may include a first heater 760a configured to apply heat to the first raw material.

The first supporter 720 may support a substrate of a display substrate D. The display substrate D may mean a structure stacked from the substrate 100 to the second electrode 223 of FIG. 9A. In this case, the first supporter 720 may be formed in various shapes. As an example, the first supporter 720 may include a shuttle, an electrostatic chuck, an adhesive chuck, and the like disposed inside the first chamber 710. In another embodiment, the first supporter 720 may include a separate frame disposed inside the first chamber 710. Hereinafter, for convenience of description, a case where the first supporter 720 includes a separate frame is mainly described in detail.

The first raw material may be deposited in a plurality of regions disposed apart from each other in the substrate of the display substrate D. After deposition is completed, the substrate of the display substrate D may be separated into a plurality of portions to form a plurality of display devices. In another embodiment, the first raw material may be deposited on the entire surface of the substrate of the display substrate D. In this case, the first opening 752a may be formed over the entire surface of the first mask sheet 752. Particularly, in this case, after deposition is completed, the substrate of the display substrate D may form one display device. However, hereinafter, for convenience of description, a case where the first raw material is deposited in a plurality of regions disposed apart from each other in the substrate of the display substrate D is mainly described in detail.

The second supporter 730 may be disposed between the first supporter 720 and the first deposition source 760. In this case, the first mask assembly 750 may sit on and be supported by the second supporter 730. In this case, the second supporter 730 may align the first mask assembly 750 and the substrate of the display substrate D by varying the displacement of the first mask assembly 750 within a small range.

The first supporter 720 and the second supporter 730 may be separated from each other to operate independently. In another embodiment, the first supporter 720 and the second supporter 730 may be integrally formed to move simultaneously. Hereinafter, for convenience of description, a case where the first supporter 720 and the second supporter 730 are integrally formed to move simultaneously, is mainly described in detail.

The first suction portion 770 may be connected to the first chamber 710 to maintain the pressure inside the first chamber 710 at a constant level. In this case, the first suction portion 770 may include a first connection pipe 771 connected to the first chamber 710, and a first pump 772 disposed in the first connection pipe 771.

The first vision portion 740 may include a camera. In this case, the first vision portion 740 may capture image data indicating the positions of the substrate of the display substrate D and the first mask assembly 750, and provide required data when aligning the substrate of the display substrate D and the first mask assembly 750.

When examining an operation of the apparatus 700 for manufacturing the first display device, the first suction portion 770 may adjust the pressure inside the first chamber 710 to be similar to atmospheric pressure. The first gate valve 710a may be opened to open the open portion of the first chamber 710.

When the first gate valve 710a is opened, the substrate of the display substrate D and the first mask assembly 750 may be inserted from the outside of the first chamber 710 to the inside of the first chamber 710. In this case, the substrate of the display substrate D and the first mask assembly 750 may be moved through a robot arm, a shuttle, or the like. In another embodiment, the first supporter 720 and the second supporter 730 may be formed in the form of a shuttle, sit the substrate of the display substrate D and the first mask assembly 750 on the first supporter 720 and the second supporter 730 in the outside, and then move the first supporter 720 and the second supporter 730 to the inside of the first chamber 710. In this case, each of the first supporter 720 and the second supporter 730 may be a shuttle, or the first supporter 720 and the second supporter 730 may be in the form of a shuttle that is integral with each other.

When the substrate of the display substrate D and the first mask assembly 750 enter the inside of the first chamber 710, the first gate valve 710a may operate to close the first chamber 710, and then, the first suction portion 770 may operate to maintain the pressure inside the first chamber 710 at a near vacuum state. In addition, the first deposition source 760 may vaporize or sublimate the first raw material to deposit the first raw material on the substrate of the display substrate D through the first mask assembly 750. In this case, the first raw material may pass through the first opening 752a in the first mask sheet 752 and be deposited in a preset pattern on the substrate of the display substrate D.

The first raw material may be deposited on the substrate of the display substrate D to shield each emission area. In this case, each first raw material may be disposed on the second electrode 223 disposed a portion of the first electrode 221. That is, each first raw material may be disposed to completely shield each first electrode 221 in a plan view. As an example, the first raw material deposited on the substrate of the display substrate D may be in the form in which the first protective layer WAL1, the second protective layer WAL2, and the third protective layer WAL3 shown in FIG. 9 are disposed.

That is, referring to FIG. 10C, the first raw material passing through the first opening 752a may form the third protective layer WAL3 by being disposed in a portion corresponding to the third emission area EA3 (see FIG. 9A). In this case, the third protective layer WAL3 may completely shield a portion of the second electrode 223 disposed on a portion of the first electrode 221 exposed through the bank layer 215.

Accordingly, in the apparatus 700 for manufacturing the first display device and the method of manufacturing the display device, each protective layer may be precisely disposed on a portion of the bank layer 215 corresponding to each opening.

There may be various methods of disposing each protective layer other than the above method. Hereinafter, a method of disposing each protective layer on the second electrode 223 other than the above method is described in detail. In addition, because methods of disposing a first bank layer, a second bank layer, and the third protective layer WAL3 are similar to each other, for convenience of description, a method of disposing the third protective layer WAL3 on the second electrode 223 other than the above method is described below in detail.

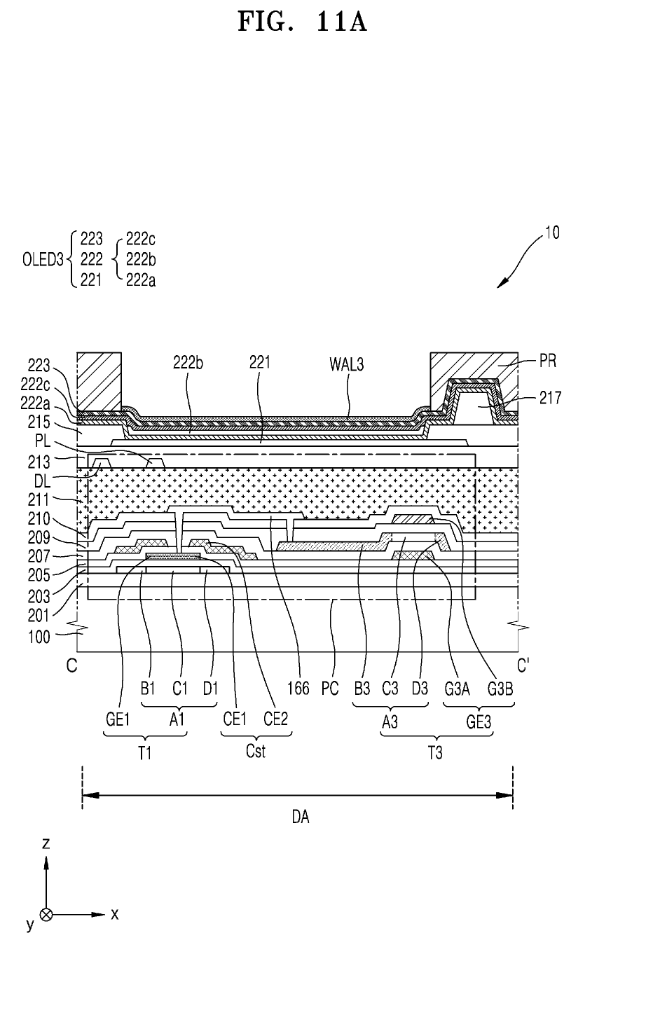

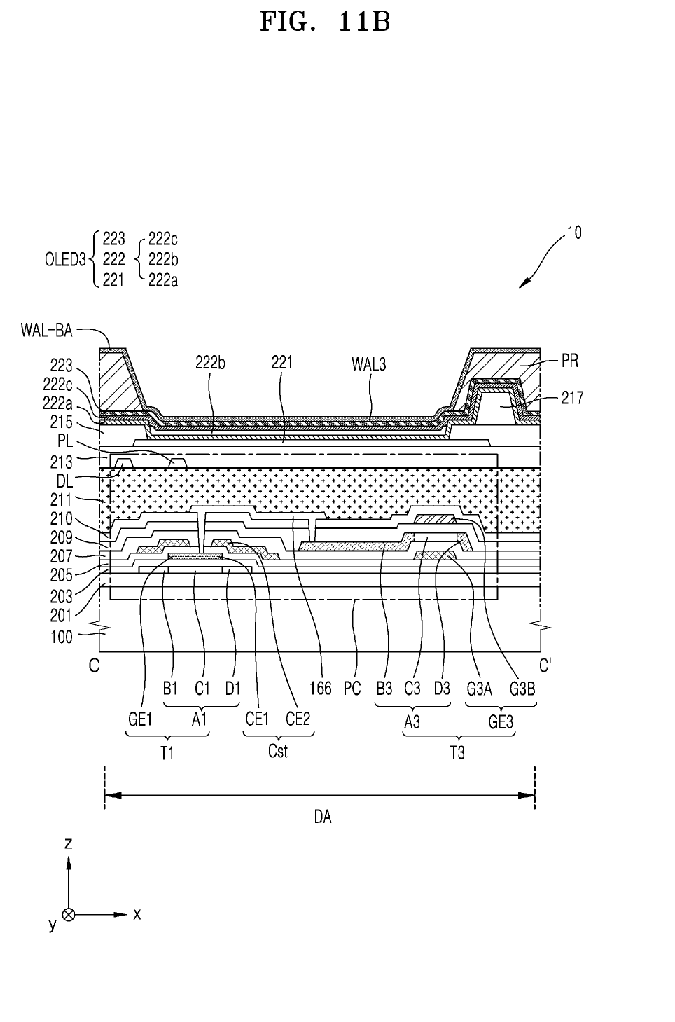

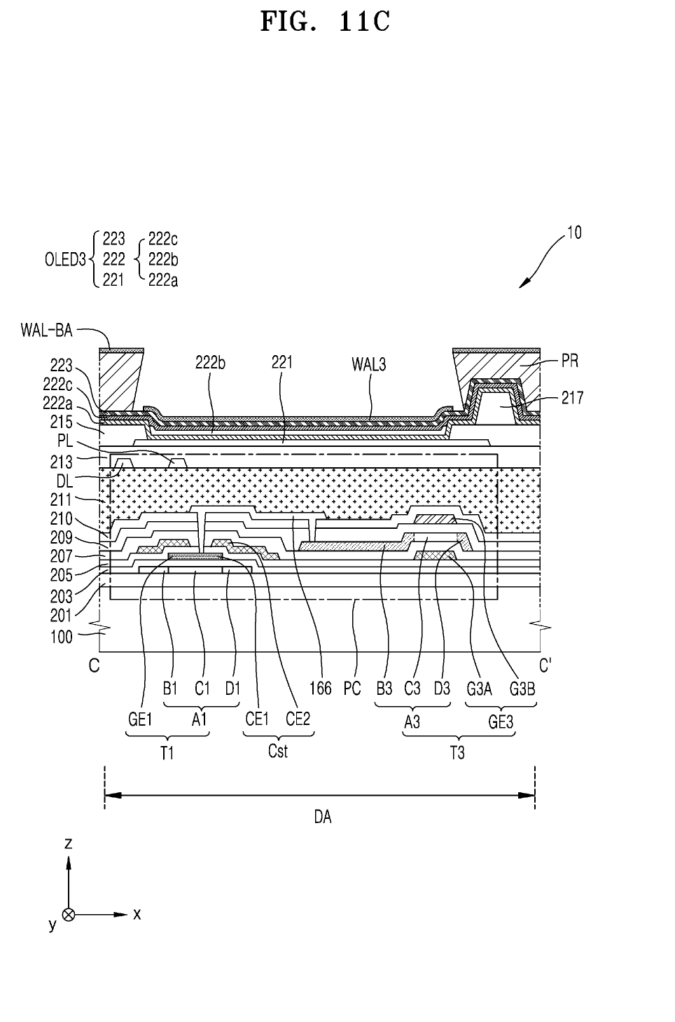

FIGS. 11A to 11C are schematic cross-sectional views showing some of a method of manufacturing a display device according to another embodiment. In FIGS. 11A to 11C, the same reference numerals as those in FIG. 8 denote the same components.

Referring to FIGS. 11A to 11C, the third protective layer WAL3 may be disposed on the substrate 100 of the display substrate D by patterning photoresist PR. As an example, the spacer 217 and the second electrode 223 are disposed on the bank layer 215, and then the photoresist PR may be disposed on the second electrode 223.

In this case, the photoresist PR may include an opening area in a portion corresponding to the opening of the bank layer 215. That is, the photoresist PR may be disposed on the entire surface of the second electrode 223, and then, a portion of the photoresist PR corresponding to the opening of the bank layer 215 may be removed by performing exposing and developing processes. In this case, a planar shape of a region from which the photoresist PR is removed may be larger than a planar shape (e.g., the third emission area EA3 shown in FIG. 8) of the first electrode 221 exposed through the bank layer 215.

Then, as shown in FIG. 11A, the third protective layer WAL3 may be disposed on the second electrode 223 by supplying, in the opening area of the photoresist PR, the first raw material, which is the protective layer-forming material similarly to the description in FIG. 10A, or supplying the first raw material, which is the protective layer-forming material forming the third protective layer WAL3 in the form of ink through a nozzle and the like. In this case, although FIG. 11A shows the boundary of the cross-section of the photoresist PR is a straight line, the boundary is not limited thereto and the boundary may be an oblique line as the boundary of the cross-section of the photoresist PR shown in FIGS. 11B or 11C described below.

In another embodiment, as shown in FIGS. 11B and 11C, a first raw material WAL-BA may be disposed on the second electrode 223 and the photoresist PR by supplying, on the second electrode 223 exposed through the photoresist PR and the photoresist PR, the first raw material WAL-BA, which is the protective layer-forming material similarly to the description in FIG. 10A, or supplying the first raw material WAL-BA, which is the protective layer-forming material forming the third protective layer WAL3, in the form of ink through a nozzle and the like. In this case, the photoresist PR shown in FIG. 11B may be a positive photoresist, and the photoresist PR shown in FIG. 11C may be a negative photoresist. In this case, in FIG. 11B, the first raw material WAL-BA may be integrally disposed on the second electrode 223 and the photoresist PR, and in FIG. 11C, the first raw materials WAL-BA disposed on disposed on the photoresist PR and the second electrode 223 may be separated from each other.

Then, the photoresist PR may be removed. In this case, when removing the photoresist PR, the first raw material WAL-BA disposed on the photoresist PR may be removed together with the photoresist PR. The first raw material WAL-BA offset from the photoresist PR may remain on the second electrode 223.

The first protective layer and the second protective layer may be also disposed on the second electrode 223 in a similar manner to the method of forming the third protective layer WAL3 described above.

Accordingly, in the method of manufacturing the display device, each protective layer may be precisely disposed on a portion corresponding to each opening of the bank layer 215.

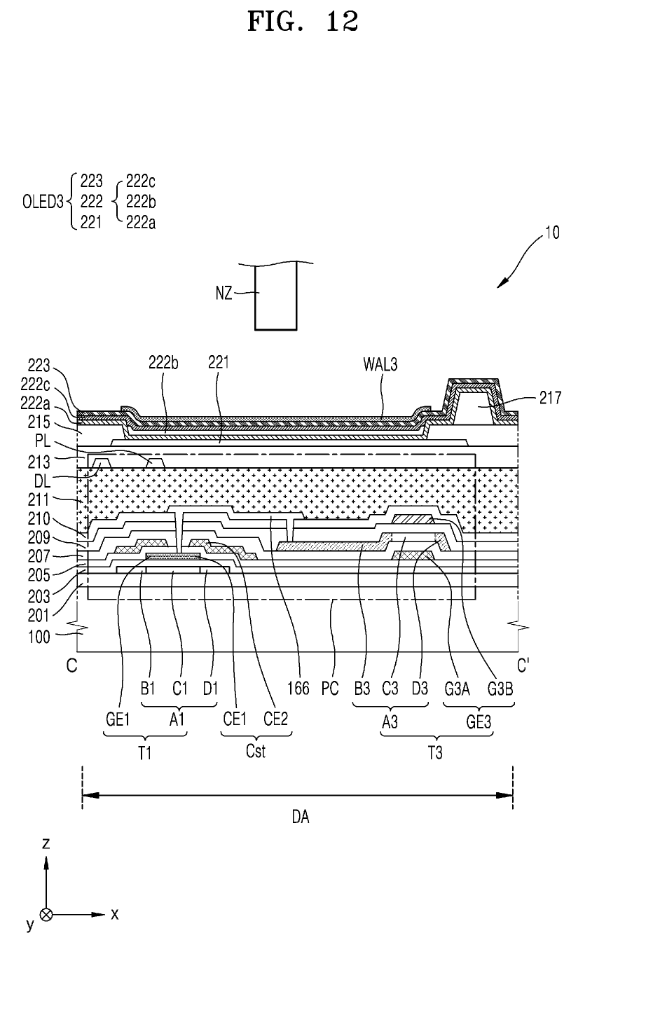

FIG. 12 is a schematic cross-sectional view showing some of the method of manufacturing the display device according to another embodiment. In FIG. 12, the same reference numerals as those in FIG. 8 denote the same components.

Referring to FIG. 12, the third protective layer WAL3 may be disposed on the second electrode 223 using an inkjet printing method.

Specifically, the first raw material forming the third protective layer WAL3 may be disposed on the second electrode 223 through a nozzle NZ. In this case, the nozzle NZ may supply the first raw material forming the third protective layer WAL3 in the form of droplets on the second electrode 223 disposed in the opening of the bank layer 215.

In this case, while a preset amount of the first raw material forming the third protective layer WAL3 is supplied on the second electrode 223, the first raw material forming the third protective layer WAL3 may be disposed on a preset region depending on a moving velocity of the nozzle NZ forming the third protective layer WAL3, a velocity of discharging the first raw material from the nozzle NZ, viscosity of the first raw material, and/or the amount of the first raw material. The third protective layer WAL3 may be disposed on the second electrode 223 by supplying energy such as heat and/or light and the like to the first raw material forming the third protective layer WAL3 and curing the first raw material forming the third protective layer WAL3. In this case, as described above, the third protective layer WAL3 may have a planar shape that is larger than the planar shape of a portion of the second electrode 223 disposed on the first electrode 221 exposed to the outside through the bank layer 215.

The first protective layer and the second protective layer may be also disposed on the second electrode 223 in a similar manner to the method of forming the third protective layer WAL3 described above.

Accordingly, in the method of manufacturing the display device, each protective layer may be precisely disposed on a portion corresponding to each opening of the bank layer 215.

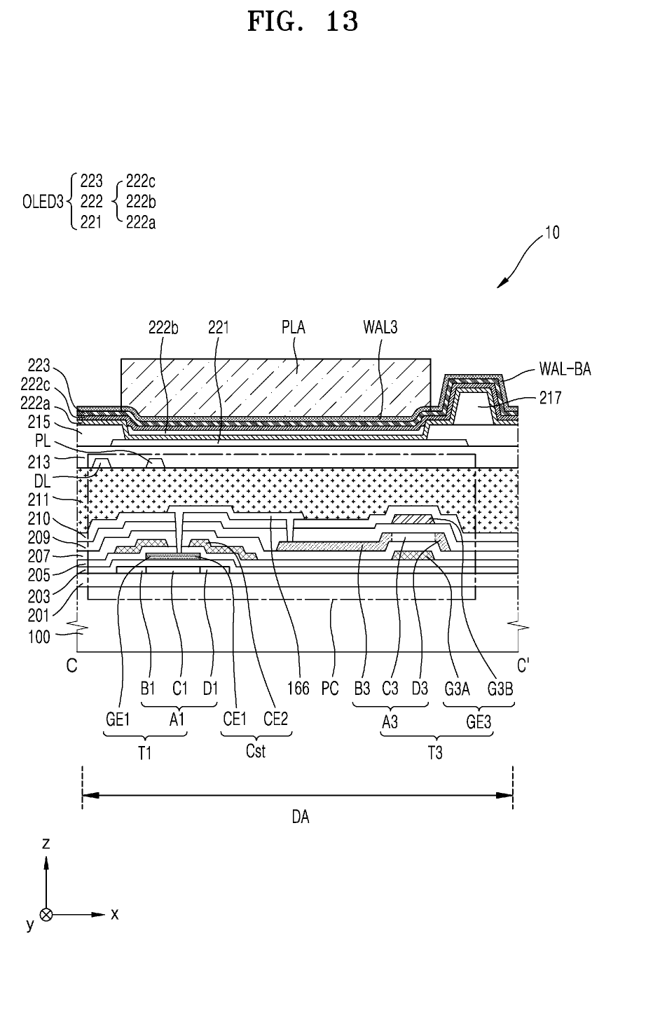

FIG. 13 is a schematic cross-sectional view showing some of the method of manufacturing the display device according to another embodiment. In FIG. 13, the same reference numerals as those in FIG. 8 denote the same components.

Referring to FIG. 13, to dispose the third protective layer WAL3 on the second electrode 223, the first raw material WAL-BA, which is the protective layer-forming material forming the third protective layer WAL3, may be disposed on the entire surface of the second electrode 223. In this case, as described with reference to FIGS. 11A to 11C, the first raw material WAL-BA may be provided as described with reference to FIG. 10A, or disposed on the entire surface of the second electrode 223 through the nozzle and the like. Then, a blocking layer PLA may be disposed on a portion of the first raw material WAL-BA. In this case, the blocking layer PLA may include the photoresist and the like.

The blocking layer PLA may correspond to a portion in which the third protective layer WAL3 is to be formed. As an example, the planar shape of the blocking layer PLA may correspond to the planar shape of the third protective layer WAL3 shown in FIG. 8. That is, the planar shape of the blocking layer PLA may be equal or almost similar to the planar shape of the third emission area EA3 shown in FIG. 8. Then, a portion of the first raw material WAL-BA not shielded by the blocking layer PLA may be removed. In addition, after the first raw material WAL-BA excluding the third protective layer WAL3 is removed, the blocking layer PLA may be removed.

The first protective layer and the second protective layer may be also disposed on the second electrode 223 in a similar manner to the method of forming the third protective layer WAL3 described above.

Accordingly, in the method of manufacturing the display device, each protective layer may be precisely disposed on a portion corresponding to each opening of the bank layer 215.

At least two of the first protective layer, the second protective layer, and the third protective layer may be formed using different methods among the methods described with reference to FIG. 10A, FIGS. 11A to 11C, and FIGS. 12 and 13.

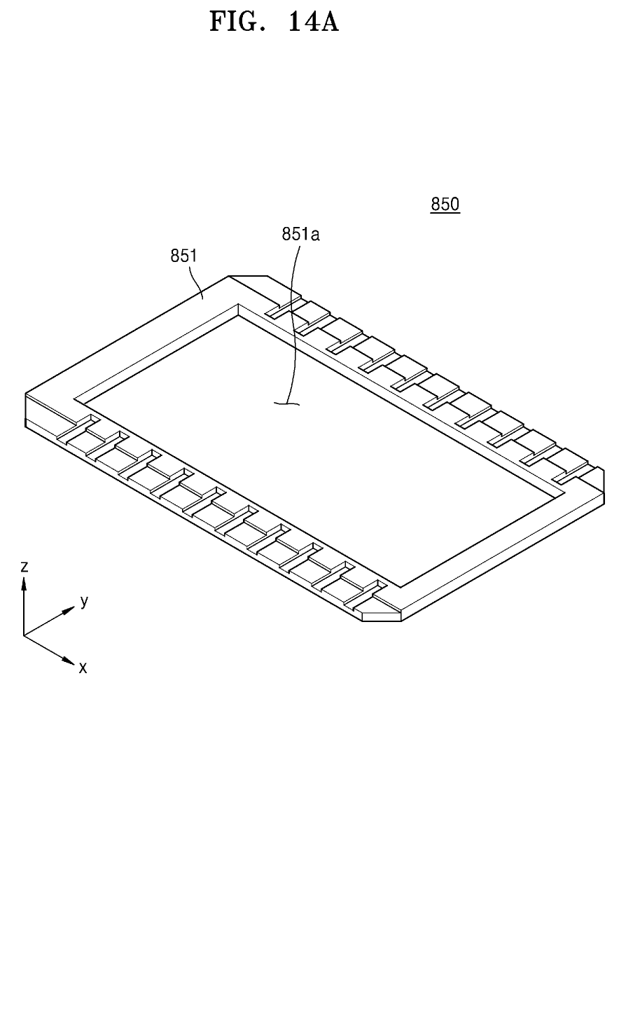

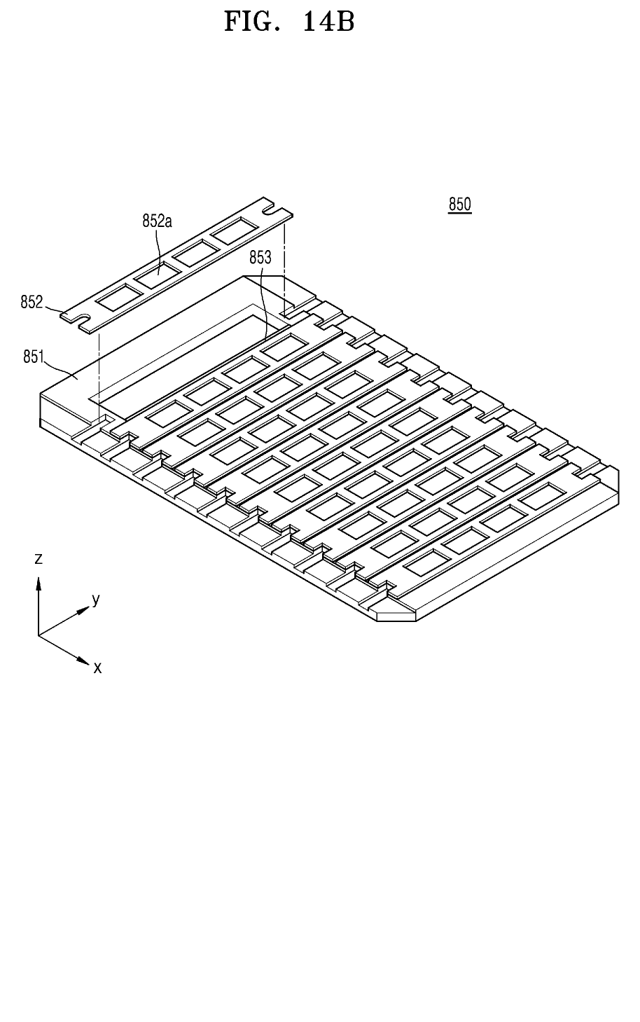

FIGS. 14A and 14B are schematic perspective views of a second mask assembly of an apparatus for manufacturing a second display device according to an embodiment.

The apparatus for manufacturing the second display device may include a second chamber, a second mask assembly 850, a second deposition source, a third supporter, a fourth supporter, a second suction portion, and a second vision portion. In this case, because the second chamber, the second deposition source, the third supporter, the fourth supporter, the second suction portion, and the second vision portion are equal or similar to the first chamber 710, the first deposition source 760, the first supporter 720, the second supporter 730, the first suction portion 770, and the first vision portion 740, detailed descriptions thereof are omitted.

In an embodiment, the second mask assembly 850 may include a second mask frame 851 as shown in FIG. 14A. In this case, the second mask frame 851 may include (i.e., define) one second opening 851a.

In another embodiment, the second mask assembly 850 may include the second mask frame 851, and at least one second mask sheet 852 disposed on the second mask frame 851 as shown in FIG. 14B. In an embodiment, one second mask sheet 852 may shield the second opening of the second mask frame 851. In another embodiment, as shown in FIG. 14B, a plurality of second mask sheets 852 may be disposed on the second mask frame 851. In this case, the second mask sheet 852 may include at least one third opening 852a. In the case where the second mask sheet 852 includes (i.e., defines) a plurality of third openings 852a, some of the plurality of first openings 752a shown in FIG. 10B may form one group, and each third opening 852a may be disposed to correspond to each of the plurality of groups apart from each other. In addition, one third opening 852a may be a region corresponding to a display area of one display device.

Hereinafter, for convenience of description, a case where the second mask assembly 850 includes only the second mask frame 851 as shown in FIG. 14A is mainly described in detail.

In the apparatus for manufacturing the second display device, the auxiliary electrode 224 may be disposed on each protective layer and second electrode 223.

Specifically, as described above, each protective layer is disposed on the second electrode 223, and then the substrate on which the second electrode and each protective layer are disposed may be disposed in the inside of the second chamber. In this case, the second mask assembly and the substrate may be disposed in the inside of the second chamber. In this case, a method of disposing the substrate and the second mask assembly in the inside of the second chamber may be similar to the method of disposing the substrate and the first mask assembly 750 in the inside of the first chamber 710 described with reference to FIGS. 10A to 10C.

Then, the second deposition source may supply a second raw material, which is an auxiliary electrode-forming material and a second deposition material, toward the substrate. The second raw material may be a material forming the auxiliary electrode described above. In this case, the second raw material may be disposed on the second electrode through the second opening 851a. The second raw material may be disposed on the entire surface of the second electrode. As an example, the second raw material may be supplied to the entire display area DA of the substrate 100 shown in FIG. 6.

The second raw material may not be disposed on each protective layer, and the second raw material may be disposed on only the second electrode where each protective layer is not present. In this case, the second raw material may form the auxiliary electrode 224 shown in FIGS. 8, 9A, and 9B.

In this case, in the apparatus for manufacturing the second display device, the auxiliary electrode 224 may be disposed in a region where each protective layer is not disposed (i.e., may be offset from each protective layer). Specifically, in the case where the second raw material is disposed on each protective layer, because bonding force between the second raw material and each protective layer is weak, the second raw material may not be adsorbed on the upper surface of each protective layer. Through this, the second raw material is not disposed on each protective layer and may be disposed on only the second electrode 223 where the protective layer is not present.

In this case, because the auxiliary electrode is disposed on the second electrode where each protective layer is not present, a total resistance of the auxiliary electrode and a portion of the second electrode on which the auxiliary electrode is disposed, may be reduced compared to a case where only the second electrode is present. Through this, the IR-drop may be reduced in the display area while the display device operates.

In the case where the auxiliary electrode is formed, the material forming the auxiliary electrode may be supplied using an inkjet method through the nozzle as in FIG. 12.

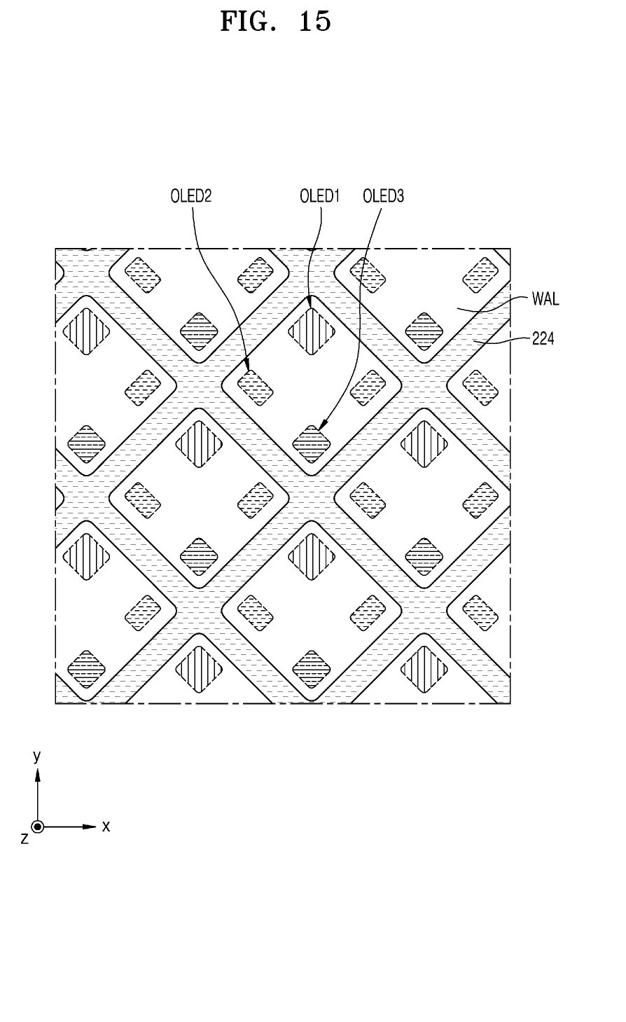

FIG. 15 is a schematic plan view of a portion of the display area of the display device according to another embodiment.

Referring to FIG. 15, a display device 10 may include the protective layer WAL, the first organic light-emitting diode OLED1, the second organic light-emitting diode OLED2, the third organic light-emitting diode OLED3, and the auxiliary electrode 224. In this case, the display device 10 may include a structure equal or similar to the cross-sectional structure shown in FIGS. 9A and 9B in addition to the above construction.

In a plan view, the protective layer WAL may shield at least two of the first organic light-emitting diode OLED1, the second organic light-emitting diode OLED2, and the third organic light-emitting diode OLED3. Hereinafter, for convenience of description, a case where the protective layer WAL simultaneously shields the first organic light-emitting diode OLED1, the second organic light-emitting diode OLED2, and the third organic light-emitting diode OLED3 is mainly described in detail.

The plurality of protective layers WAL may be disposed apart from each other. One protective layer WAL may shield one first organic light-emitting diode OLED1, two second organic light-emitting diodes OLED2, and one third organic light-emitting diode OLED3. The protective layer WAL may be disposed on the bank layer 215 (see FIG. 8) and/or the spacer 217 (see FIG. 8) disposed between the first organic light-emitting diode OLED1 and the second organic light-emitting diode OLED2, between the first organic light-emitting diode OLED1 and the third organic light-emitting diode OLED3, between the second organic light-emitting diode OLED2 and the second organic light-emitting diode OLED2, and between the second organic light-emitting diode OLED2 and the third organic light-emitting diode OLED3. In addition, the planar shape of each protective layer WAL may be larger than an arbitrary planar shape connecting the edges of the first organic light-emitting diode OLED1, the second organic light-emitting diode OLED2, and the third organic light-emitting diode OLED3. The planar shape of the protective layer WAL is not limited thereto and may be an island shape. In this case, the planar shape of the protective layer WAL may be a polygon, a circular shape, an elliptical shape, and/or an irregular shape other than a polygon, a circular shape, and an elliptical shape.

The auxiliary electrode 224 may be disposed between the protective layers WAL apart from each other. In this case, the auxiliary electrode 224 may have a grip shape.

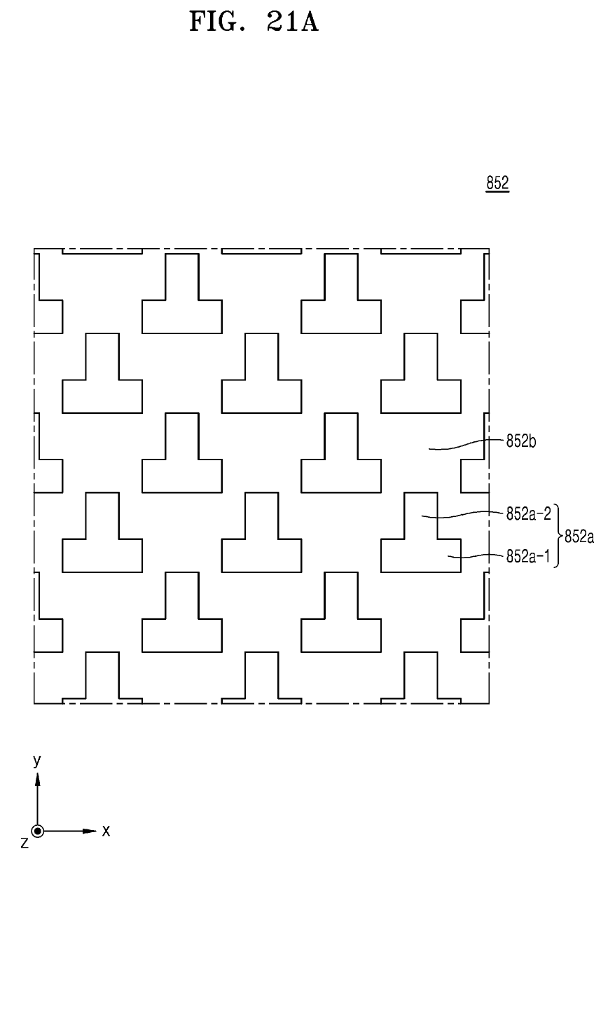

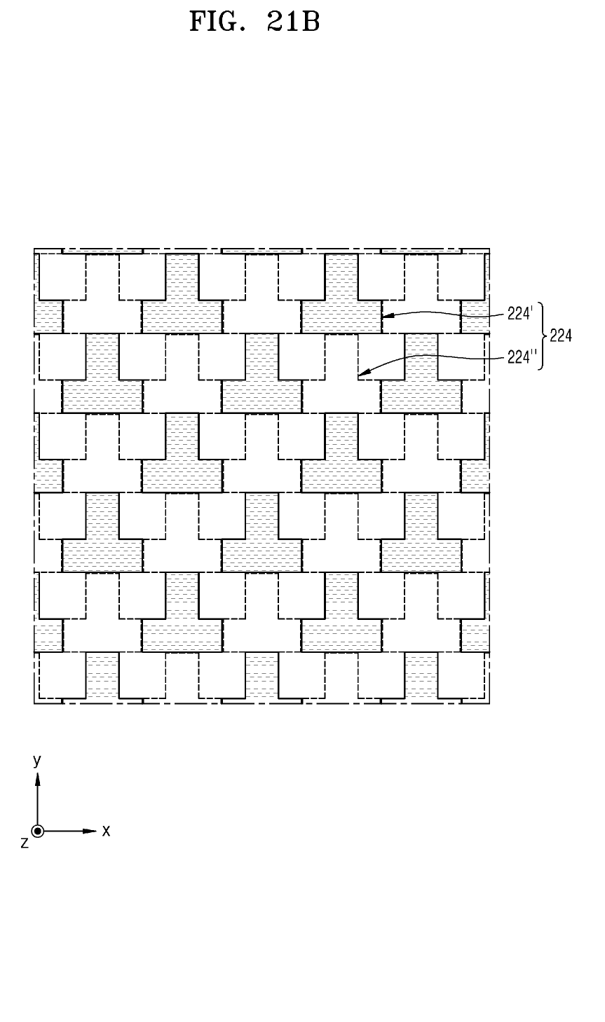

The protective layer WAL may be formed using a process equal or similar to the process described with reference to FIGS. 10C, 11A to 11C, 12, and 13. In addition, the auxiliary electrode 224 may be formed through the process described with reference to FIGS. 14A and 14B, or formed by supplying the second raw material in the entire display area through the nozzle and the like. In another embodiment, the auxiliary electrode 224 may be formed by depositing the second raw material through a structure similar to FIG. 21A described below, or be completed by supplying the second raw material through the nozzle and the like to form a portion of the auxiliary electrode 224, and then forming the other portion of the auxiliary electrode 224.

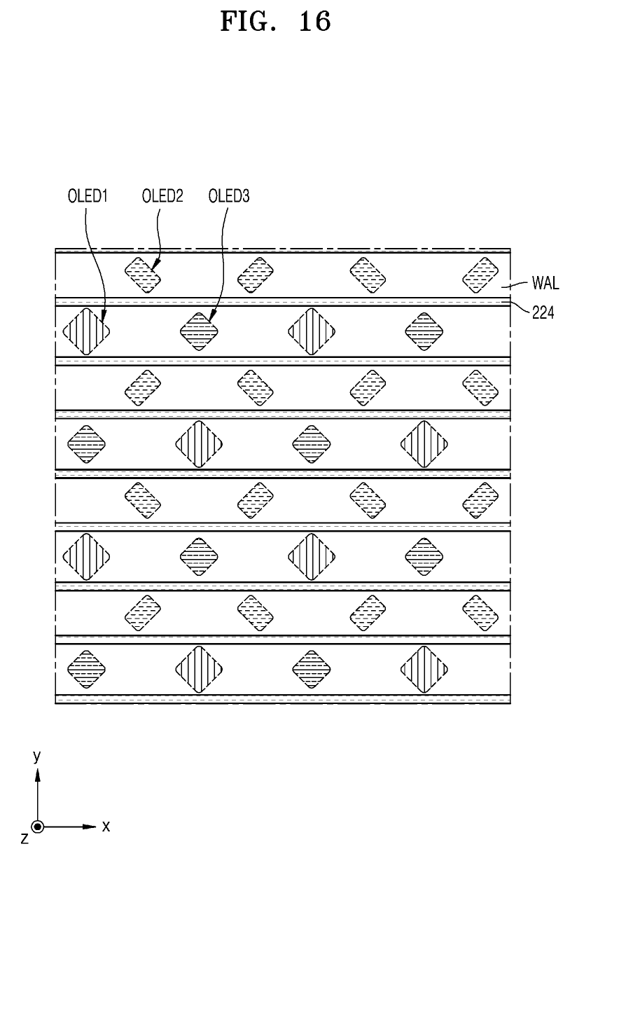

FIG. 16 is a schematic plan view of a portion of the display area of the display device according to another embodiment.

Referring to FIG. 16, a display device 10 may include the protective layer WAL, the first organic light-emitting diode OLED1, the second organic light-emitting diode OLED2, the third organic light-emitting diode OLED3, and the auxiliary electrode 224. In this case, the display device 10 may include a structure equal or similar to the cross-sectional structure shown in FIGS. 9A and 9B in addition to the above construction.

The protective layer WAL and the auxiliary electrode 224 may have a line shape. As an example, the protective layer WAL may shield a plurality of organic light-emitting diodes arranged in the first direction (e.g., an x direction in FIG. 16). As an example, one protective layer WAL may shield the second organic light-emitting diodes OLED2 apart from each other in the first direction in FIG. 16. In addition, another protective layer WAL may be disposed to shield the first organic light-emitting diode OLED1 and the third organic light-emitting diode OLED3 disposed alternately in the first direction in FIG. 16.

A plurality of protective layers WAL may be provided to be apart from each other in the second direction (e.g., a y direction in FIG. 16). In this case, the protective layer WAL may shield not only the first emission area of the first organic light-emitting diode OLED1, the second emission area of the second organic light-emitting diode OLED2, and the third emission area of the third organic light-emitting diode OLED3, but also the bank layer and/or the spacer disposed between the second emission areas, and the bank layer and/or the spacer disposed between the first emission area and the third emission area.

The auxiliary electrode 224 may extend in the first direction and be disposed between the first organic light-emitting diode OLED1 and the second organic light-emitting diode OLED2 and between the second organic light-emitting diode OLED2 and the third organic light-emitting diode OLED3 disposed in zigzags in the second direction. In this case, the auxiliary electrode 224 may be provided in plurality, and the plurality of auxiliary electrodes 224 may be apart from each other in the second direction.

In addition to that shown in FIG. 16, the protective layer WAL and the auxiliary electrode 224 may be disposed in a line shape in the second direction. In another embodiment, the protective layer WAL may be arranged in a dotted line shape in the first direction or second direction.

The protective layer WAL may be formed using a process equal or similar to the process described with reference to FIGS. 10C, 11A to 11C, 12, and 13. In addition, the auxiliary electrode 224 may be formed through the process described with reference to FIGS. 14A and 14B, or formed by supplying the second raw material in the entire display area through the nozzle and the like. In another embodiment, the auxiliary electrode 224 may be formed by depositing the second raw material through a structure similar to FIG. 21A described below, or be completed by supplying the second raw material through the nozzle and the like to form a portion of the auxiliary electrode 224, and then forming the other portion of the auxiliary electrode 224.

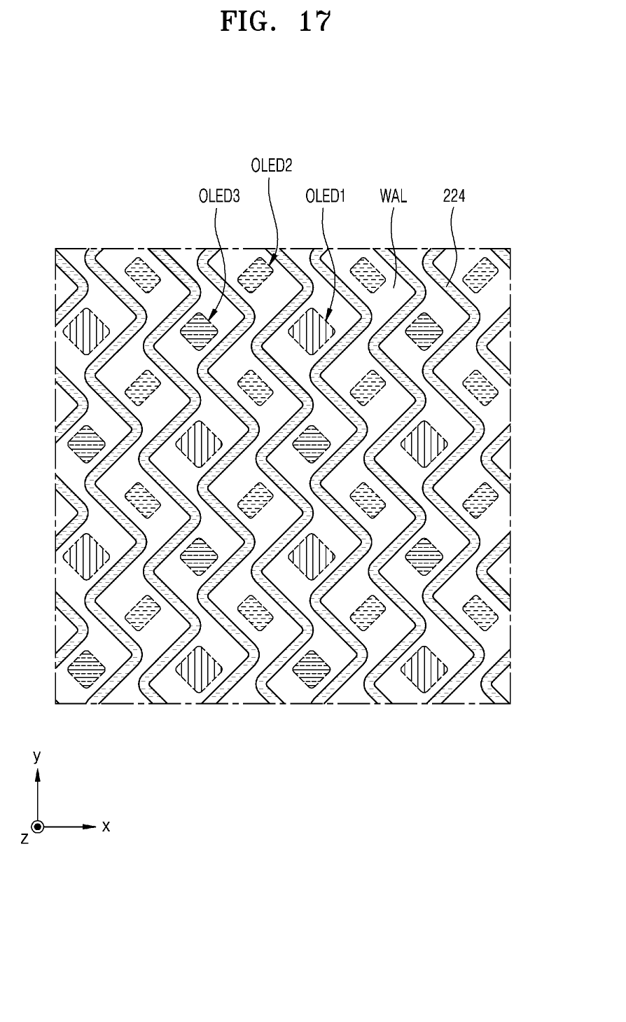

FIG. 17 is a schematic plan view of a portion of the display area of the display device according to another embodiment.

Referring to FIG. 17, the display device 10 may include the protective layer WAL, the first organic light-emitting diode OLED1, the second organic light-emitting diode OLED2, the third organic light-emitting diode OLED3, and the auxiliary electrode 224. In this case, the display device 10 may include a structure equal or similar to the cross-sectional structure shown in FIGS. 9A and 9B in addition to the above construction.

The protective layer WAL and the auxiliary electrode 224 may have a zigzag shape or serpentine shape. As an example, the protective layer WAL may shield the first organic light-emitting diode OLED1 and the third organic light-emitting diode OLED3 arranged in a line in the second direction (e.g., the y direction in FIG. 17), or shield the second organic light-emitting diodes OLED2 disposed in a line. In this case, each protective layer WAL may shield not only the first emission area of the first organic light-emitting diode OLED1, the second emission area of the second organic light-emitting diode OLED2, and the third emission area of the third organic light-emitting diode OLED3, but also the bank layer and/or the spacer disposed between the second emission areas, and the bank layer and/or the spacer disposed between the first emission area and the third emission area.

The auxiliary electrode 224 may be disposed between the protective layers WAL adjacent to each other. In this case, the auxiliary electrode 224 may be arranged in a similar shape to the protective layer WAL. The auxiliary electrodes 224 may be disposed apart from each other in the first direction.

The directions of the protective layer WAL and the auxiliary electrode 224 are not limited to FIG. 17 and may be arranged in the first direction.

The protective layer WAL may be formed using a process equal or similar to the process described with reference to FIGS. 10C, 11A to 11C, 12, and 13. In addition, the auxiliary electrode 224 may be formed through the process described with reference to FIGS. 14A and 14B, or formed by supplying the second raw material in the entire display area through the nozzle and the like. In another embodiment, the auxiliary electrode 224 may be formed by depositing the second raw material through a structure similar to FIG. 21A described below, or be completed by supplying the second raw material through the nozzle and the like to form a portion of the auxiliary electrode 224, and then forming the other portion of the auxiliary electrode 224.

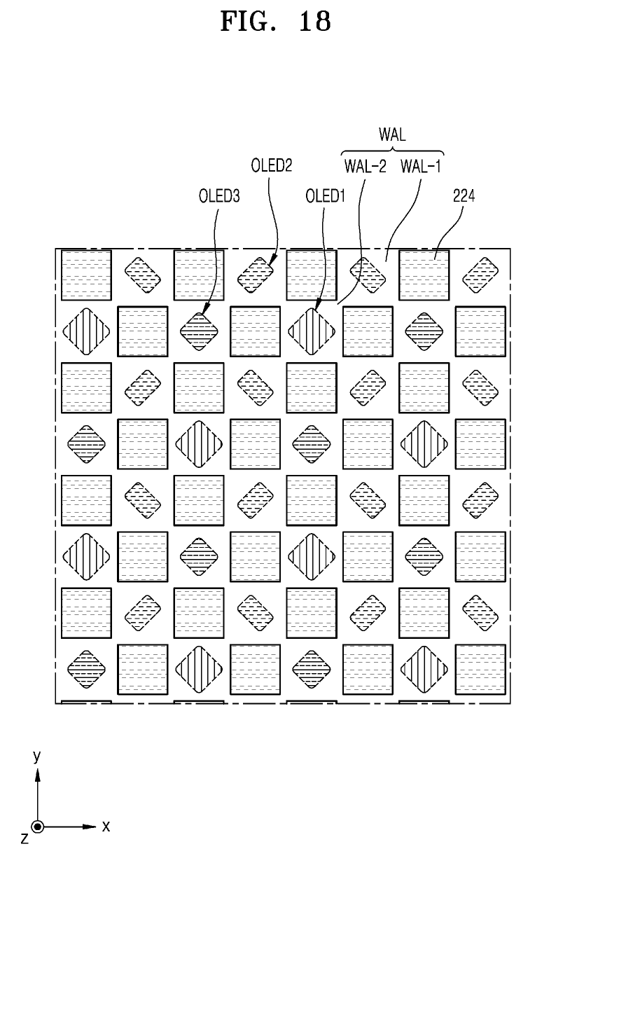

FIG. 18 is a schematic plan view of a portion of the display area of the display device according to another embodiment.

Referring to FIG. 18, the display device 10 may include the protective layer WAL, the first organic light-emitting diode OLED1, the second organic light-emitting diode OLED2, the third organic light-emitting diode OLED3, and the auxiliary electrode 224. In this case, the display device 10 may include a structure equal or similar to the cross-sectional structure shown in FIGS. 9A and 9B in addition to the above construction.

The protective layer WAL may have a mesh-like structure that includes portions connected to each other. As an example, the protective layer WAL may include a first portion WAL-1 and a second portion WAL-2, wherein the first portion WAL-1 shields the first organic light-emitting diode OLED1, the second organic light-emitting diode OLED2, or the third organic light-emitting diode OLED3, and the second portion WAL-2 connects the first portions WAL-1 adjacent to each other. In this case, a planar shape of the first portion WAL-1 may be larger than the planar shape of one of the first organic light-emitting diode OLED1, the second organic light-emitting diode OLED2, and the third organic light-emitting diode OLED3. In addition, the second portion WAL-2 may be formed less than the first portion WAL-1. The planar shape of the first portion WAL-1 is not limited to the above shape. As an example, the planar shape of the first portion WAL-1 may have a polygonal shape, a circular shape, an elliptical shape, or an irregular shape other than a polygonal shape, a circular shape, and an elliptical shape.

The auxiliary electrodes 224 may be disposed apart from each other in an island shape. The planar shape of the auxiliary electrode 224 may be various. As an example, the planar shape of the auxiliary electrode 224 may have a polygonal shape, a circular shape, an elliptical shape, or an irregular shape other than a polygonal shape, a circular shape, and an elliptical shape. In this case, the auxiliary electrode 224 may be disposed on the second electrode not to shield the emission area of each light-emitting diode. Although it is shown in FIG. 18 that the first portion WAL-1 overlaps one organic light-emitting diode, the first portion WAL-1 is not limited thereto. As an example, the first portion WAL-1 may be disposed to overlap at least two organic light-emitting diodes.

The protective layer WAL may be formed using a process equal or similar to the process described with reference to FIGS. 10C, 11A to 11C, 12, or 13. In another embodiment, the protective layer WAL may be formed by depositing the first raw material using the first mask sheet having a structure similar to FIG. 21A described below, or be completed by supplying the first raw material through the nozzle to form a portion of the protective layer WAL, and then forming the other portion of the protective layer WAL.

In addition, the auxiliary electrode 224 may be formed through the process described with reference to FIGS. 14A and 14B, or formed by supplying the raw material in the entire display area through the nozzle and the like. In another embodiment, the auxiliary electrode 224 may be formed by depositing the second raw material through a structure similar to FIG. 21A described below, or be completed by supplying the second raw material through the nozzle and the like to form a portion of the auxiliary electrode 224, and then forming the other portion of the auxiliary electrode 224.

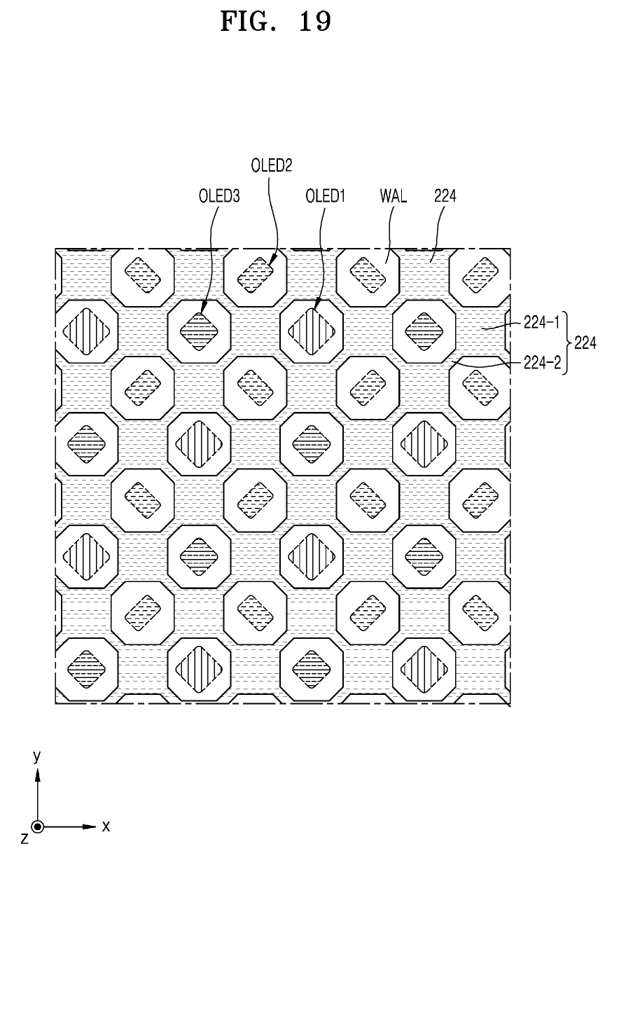

FIG. 19 is a schematic plan view of a portion of the display area of the display device according to another embodiment.

Referring to FIG. 19, the display device 10 may include the protective layer WAL, the first organic light-emitting diode OLED1, the second organic light-emitting diode OLED2, the third organic light-emitting diode OLED3, and the auxiliary electrode 224. In this case, the display device 10 may include a structure equal or similar to the cross-sectional structure shown in FIGS. 9A and 9B in addition to the above construction.

The protective layer WAL may have an island shape. In this case, the protective layer WAL may shield each of the first organic light-emitting diode OLED1, the second organic light-emitting diode OLED2, and the third organic light-emitting diode OLED3. In this case, the plurality of protective layers WAL may be apart from each other. In addition, each protective layer WAL may have a polygonal shape, a circular shape, an elliptical shape, or an irregular shape other than a polygonal shape, a circular shape, and an elliptical shape.

The auxiliary electrode 224 may be disposed on a portion where the protective layer WAL is not disposed (i.e., is offset from the protective layer WAL). In this case, the auxiliary electrode 224 may be in the form of a mesh. In this case, the auxiliary electrode 224 may include a first auxiliary electrode 224-1 and a second auxiliary electrode 224-2. The first auxiliary electrodes 224-1 may be disposed apart from each other. In this case, the first auxiliary electrode 224-1 may be surrounded by the first organic light-emitting diode OLED1, the second organic light-emitting diode OLED2, and the third organic light-emitting diode OLED3 that are adjacent to each other. The second auxiliary electrode 224-2 may connect the first auxiliary electrodes 224-1 adjacent to each other. In this case, the planar shape of the first auxiliary electrode 224-1 may be larger than the planar shape of the second auxiliary electrode 224-2.

Although it is shown in FIG. 19 that the protective layer WAL overlaps one organic light-emitting diode, the protective layer WAL is not limited thereto. As an example, the protective layer WAL may be disposed to overlap at least two organic light-emitting diodes. The protective layer WAL may be formed using a process equal or similar to the process described with reference to FIGS. 10C, 11A to 11C, 12, or 13. In addition, the auxiliary electrode 224 may be formed through the process described with reference to FIGS. 14A and 14B, or formed by supplying the second raw material in the entire display area through the nozzle and the like. In another embodiment, the auxiliary electrode 224 may be formed by depositing the second raw material through a structure similar to FIG. 21A described below, or be completed by supplying the second raw material through the nozzle and the like to form a portion of the auxiliary electrode 224, and then forming the other portion of the auxiliary electrode 224.

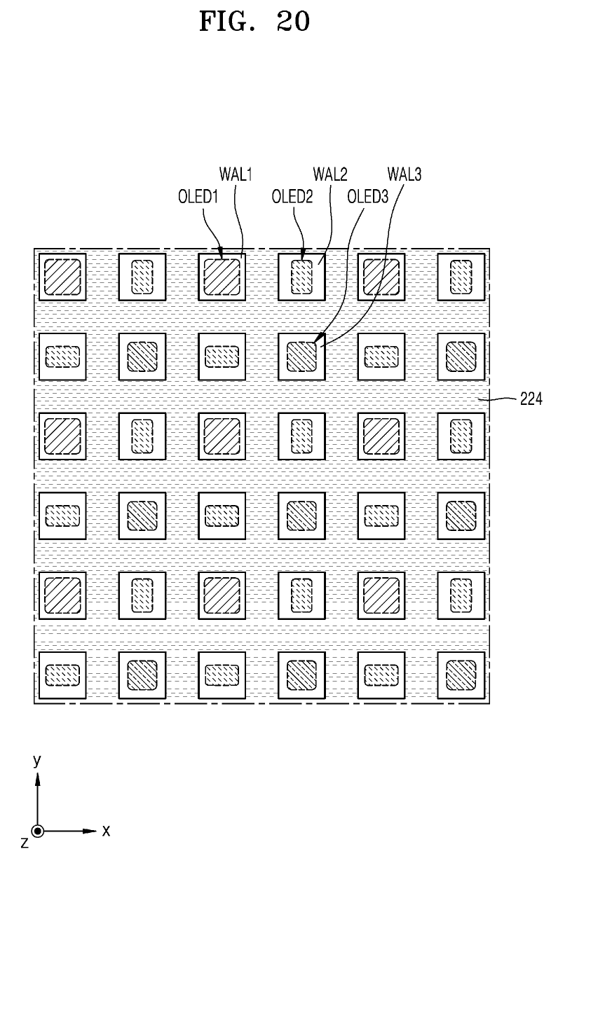

FIG. 20 is a schematic plan view of a portion of the display area of the display device according to another embodiment.

Referring to FIG. 20, the display device 10 may include the protective layer WAL, the first organic light-emitting diode OLED1, the second organic light-emitting diode OLED2, the third organic light-emitting diode OLED3, and the auxiliary electrode 224. The first organic light-emitting diode OLED1, the second organic light-emitting diode OLED2, and the third organic light-emitting diode OLED3 may be disposed without being tilted with respect to the first direction and the second direction. For example, each of the first organic light-emitting diode OLED1, the second organic light-emitting diode OLED2, and the third organic light-emitting diode OLED3 may have the have sides that extend in the x direction and the y direction. In this case, the display device 10 may include a structure equal or similar to the cross-sectional structure shown in FIGS. 9A and 9B in addition to the above construction.

The protective layers WAL may be disposed in island shapes to be apart from each other. In this case, the protective layers WAL may be disposed apart from each other. The auxiliary electrode 224 may be disposed in the form of a mesh. In this case, the auxiliary electrode 224 may be disposed between the organic light-emitting diodes adjacent to each other. In addition, the auxiliary electrode 224 may not overlap the emission area of each organic light-emitting diode.

Although it is shown in FIG. 20 that the protective layer WAL overlaps one organic light-emitting diode, the protective layer WAL is not limited thereto. As an example, the protective layer WAL may be disposed to overlap at least two organic light-emitting diodes.

The protective layer WAL may be formed using a process equal or similar to the process described with reference to FIGS. 10C, 11A to 11C, 12, or 13.

FIG. 21A is a schematic plan view of a portion of the apparatus for manufacturing the second display device according to another embodiment. FIG. 21B is a schematic plan view of a portion of the display device according to another embodiment.

The apparatus for manufacturing the second display device may include a second chamber, a second mask assembly, a second deposition source, a third supporter, a fourth supporter, a second suction portion, and a second vision portion. In this case, because the second chamber, the second deposition source, the third supporter, the fourth supporter, the second suction portion, and the second vision portion are equal or similar to those described with reference to FIGS. 14A and 14B, detailed descriptions thereof are omitted.

The second mask assembly may include a second mask frame and the second mask sheet 852 disposed on the second mask frame. In this case, because the second mask frame is equal or similar to that described with reference to FIGS. 14A and 14B, detailed description thereof is omitted.

Referring to FIGS. 21A and 21B, the second mask sheet 852 may include (i.e., define) a plurality of third openings 852a. In this case, the third opening 852a may be provided in plurality, and the plurality of third openings 852a may be disposed apart from each other. The plurality of third openings 852a may be disposed in the form of zigzags. The second mask sheet 852 may include a second blocking portion 852b disposed between the third openings 852a adjacent to each other. In this case, the second blocking portions 852b may be connected to each other.

Each third opening 852a may be in the form of a letter ‘T’. Each third opening 852a may include a third -1 opening 852a-1 extending in the first direction, and a third -2 opening 852a-2 connected to the third -1 opening 852a-1 and extending in the second direction.

A first auxiliary electrode pattern 224’ may be disposed on the second electrode through the apparatus for manufacturing the second display device. Specifically, the second raw material passing through the third opening 852a of the second mask sheet 852 shown in FIG. 21A may be disposed on the second electrode. In this case, a portion where the third -1 opening 852a-1 and the third -2 opening 852a-2 may correspond to a portion of the edge of the protective layer WAL shown in FIG. 20.

When the above process is completed, a second auxiliary electrode pattern 224” may be formed by moving the substrate and/or the second mask assembly in the first direction or second direction, and depositing the second raw material on the second electrode again. In this case, the first auxiliary electrode pattern 224’ and the second auxiliary electrode pattern 224” are connected to each other to form the auxiliary electrode 224 shown in FIG. 20. In this case, the first auxiliary electrode pattern 224’ and the second auxiliary electrode pattern 224” are connected to each other to form a shield space therein. This space may correspond to the planar shape of the protective layer WAL shown in FIG. 20.

Accordingly, the apparatus for manufacturing the second display device may complete the auxiliary electrode 224 within the same second chamber through a plurality of processes.

The apparatus for manufacturing the second display device may be used to form the shape of the auxiliary electrode 224 shown in FIG. 19. In this case, the shape of the third opening 852a may correspond to a portion of the shape of the auxiliary electrode 224, and a movement direction of the second mask assembly and/or the substrate may be an oblique direction with respect to the first direction and the second direction.

In the case where the protective layers have a shape in which the protective layers are connected to each other as in FIGS. 17 and 18, the apparatus for manufacturing the first display device may have a similar structure to a structure of the apparatus for manufacturing the second display device and may form the protective layer through a plurality of processes.

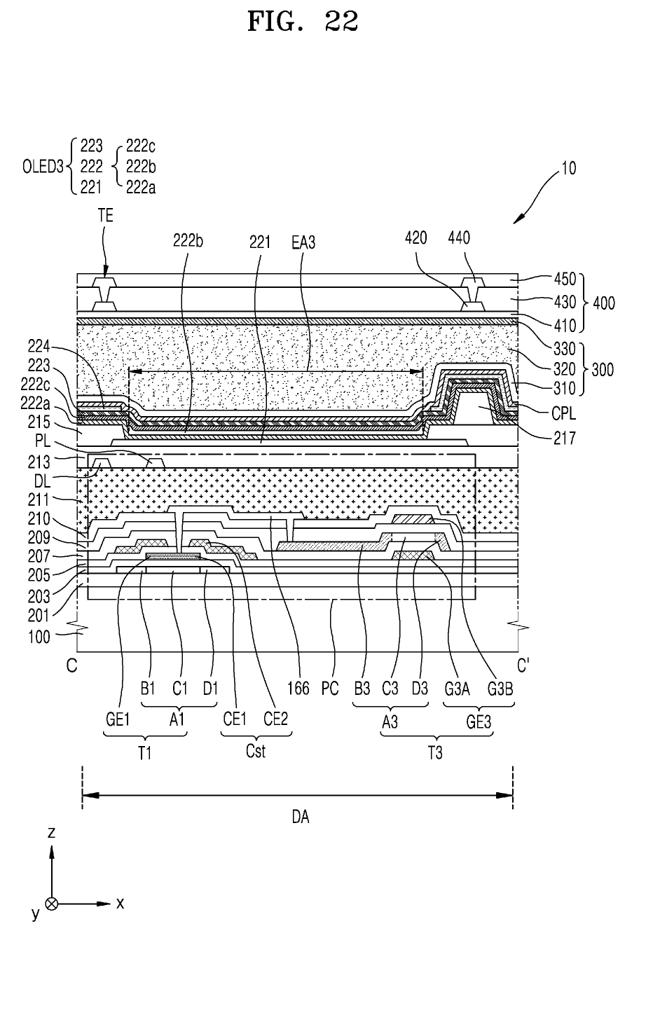

FIG. 22 is a cross-sectional view of a portion of the display device according to another embodiment.

Referring to FIG. 22, the display device 10 may include a plurality of sub-pixels including the sub-pixel circuit PC and the organic light-emitting diode disposed in the display area DA. In this case, in FIG. 22, the reference numbers used with reference to FIGS. 9A and 9B denote the same components. Hereinafter, for convenience of description, portions different from those in FIGS. 9A and 9B are described in detail. In addition, hereinafter, for convenience of description, the third organic light-emitting diode OLED3 disposed in the display area is mainly described in detail.

The display device 10 may include the auxiliary electrode 224 exposing the third emission area EA3 to the outside. In this case, the auxiliary electrode 224 may include (i.e., define) an opening area corresponding to the third emission area EA3. A size of the opening area may be equal to or greater than a size of the third emission area EA3. Through this, due to the arrangement of the auxiliary electrode 224, brightness of light emitted from the third emission area EA3 may be prevented from being reduced.

In this case, the second electrode 223 exposed through the third emission area EA3 may be in direct contact with the capping layer CPL. In addition, because the auxiliary electrode 224 and the second electrode 223 are connected to each other in a portion other than the third emission area EA3, in the case where the second power voltage is applied to the second electrode 223, IR-drop occurring in a portion of the display area is reduced, and thus, uniform and clear images may be implemented in the entire display area. The planar shape of the auxiliary electrode 224 may be various. As an example, the planar shape of the auxiliary electrode 224 may be equal or similar to the shape shown in FIGS. 8, 15, 16, 17, 18, 19 and/or FIG. 20. In this case, a portion of the protective layer WAL shown in FIGS. 8, 15, 16, 17, 18, 19 and/or FIG. 20 may be an opening area in which the auxiliary electrode 224 is not formed.

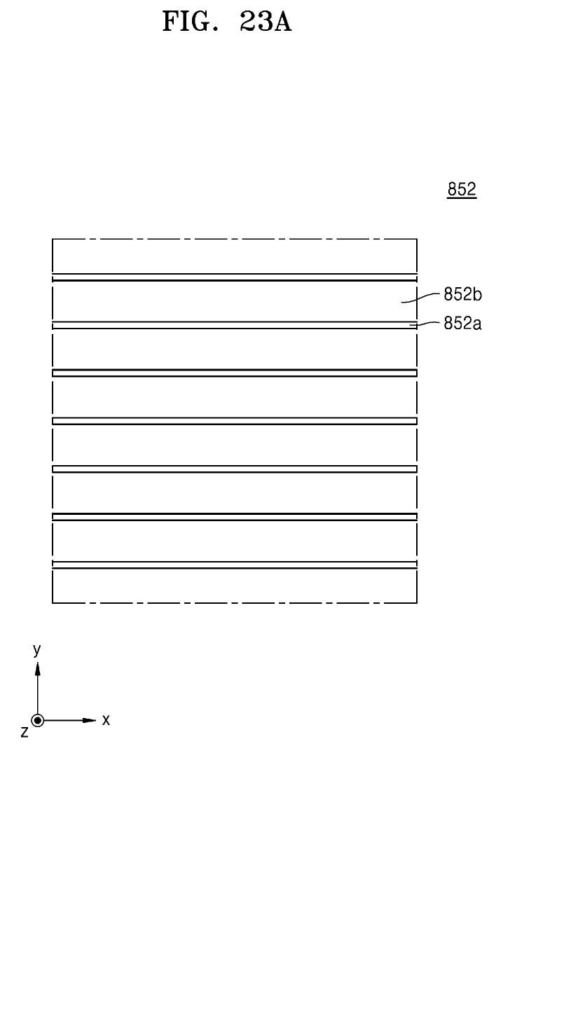

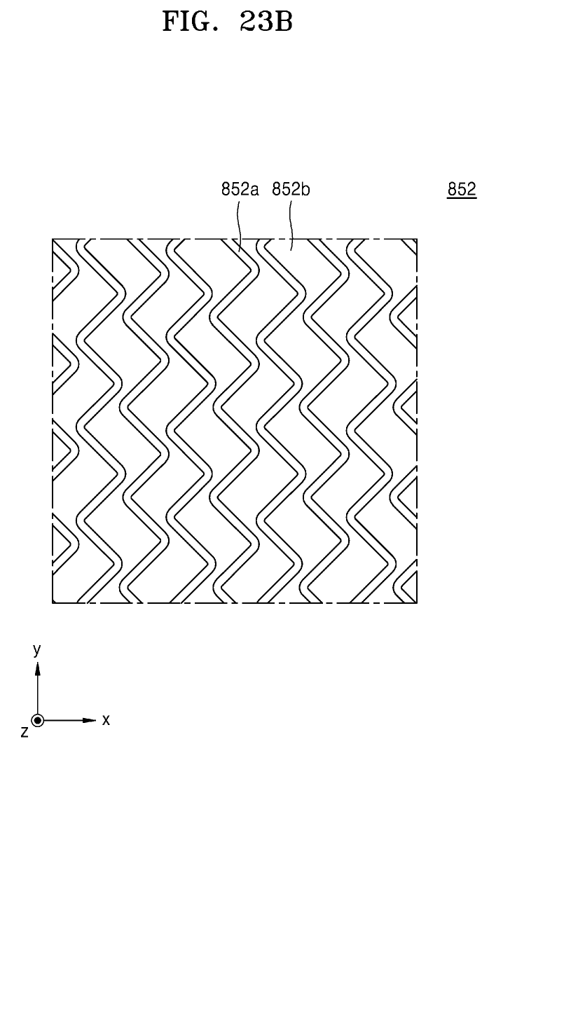

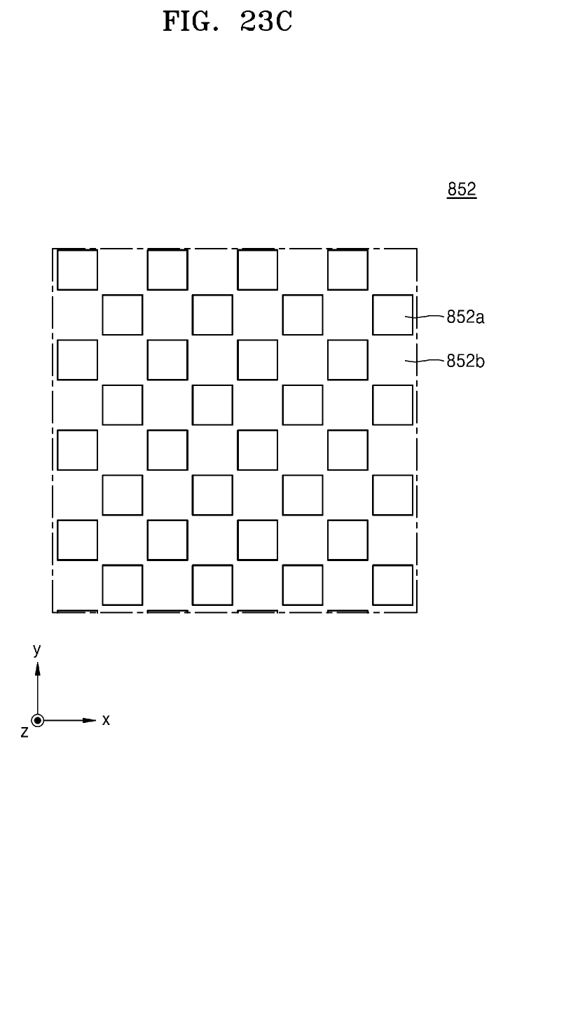

FIGS. 23A to 23C are schematic plan views showing some of an apparatus for manufacturing the display device according to another embodiment.

The apparatus for manufacturing the second display device may include a second chamber, a second mask assembly, a second deposition source, a third supporter, a fourth supporter, a second suction portion, and a second vision portion. In this case, because the second chamber, the second deposition source, the third supporter, the fourth supporter, the second suction portion, and the second vision portion are equal or similar to those described in FIG. 14, detailed descriptions thereof are omitted.

The Referring to FIG. 23A, the second mask sheet 852 of the second mask assembly may include the third opening 852a and the second blocking portion 852b. In this case, the third opening 852a and the second blocking portion 852b may be formed in a line shape. In addition, the edge of the third opening 852a may be quadrangular. In this case, the second blocking portions 852b apart from each other may be connected to each other at both ends of the second blocking portions 852b. In this case, the third opening 852a may be less than the width or length of the display area DA. In this case, the second raw material passing through the third opening 852a may form the auxiliary electrode in a line shape as shown in FIG. 16.

Referring to FIG. 23B, the second mask sheet 852 may include the third opening 852a and the second blocking portion 852b. In this case, the planar shape of the third opening 852a and the planar shape of the second blocking portion 852b may be a zigzag shape or serpentine shape.

In this case, the second blocking portion 852b may block the second raw material, and the third opening 852a may pass the second raw material. Through this, the auxiliary electrode may be formed on the second electrode by disposing the second raw material on the second electrode. In this case, the second blocking portion 852b may block the second raw material from being disposed in each emission area by shielding the emission areas of the plurality of organic light-emitting diodes. In this case, as shown in FIG. 17, the auxiliary electrode may be disposed on the second electrode.

Referring to FIG. 23C, the third openings 852a may be disposed in an island shape, and the second blocking portions 852b may be connected to each other. In this case, the third opening 852a may pass the second raw material, and the second blocking portion 852b may block the second raw material.

The second raw material passing through the third opening 852a may form the auxiliary electrode on the second electrode. The auxiliary electrode may have a shape shown in FIG. 18.

The auxiliary electrode having a shape shown in FIGS. 19 or 20 may be formed through the second mask sheet having the shape equal or similar to the shape shown in FIG. 21A. In this case, the auxiliary electrode may be formed through at least two processes.

The auxiliary electrode may be formed using an inkjet printing method. In this case, the planar shape of the auxiliary electrode may be similar to that described above, and be formed by supplying, on the second electrode, the second raw material through a nozzle in which a movement direction, a velocity, the amount of discharge, and the like are set in advance.

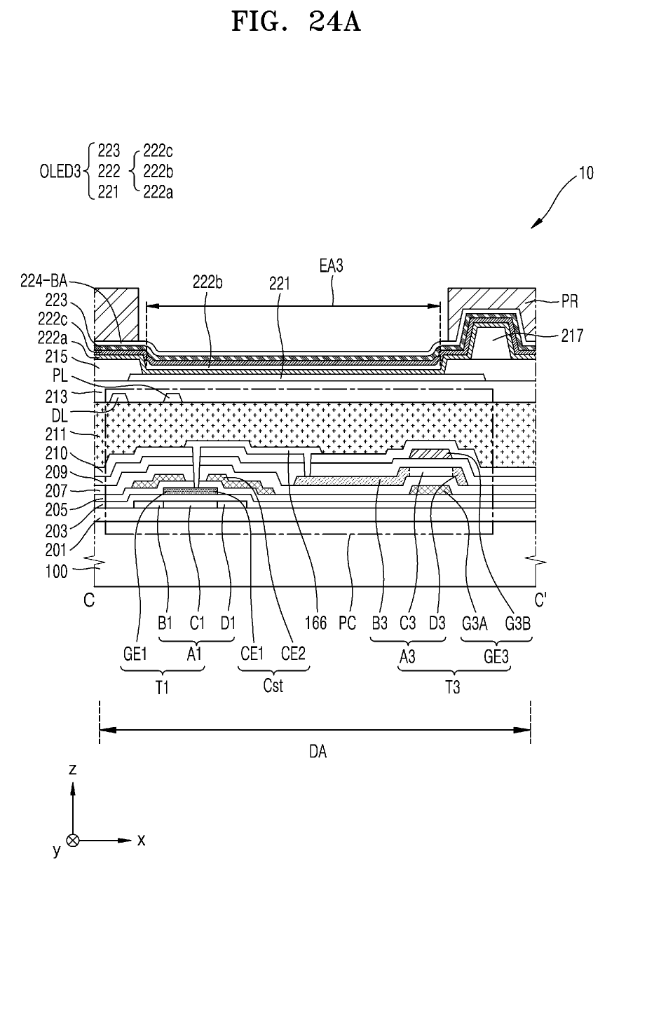

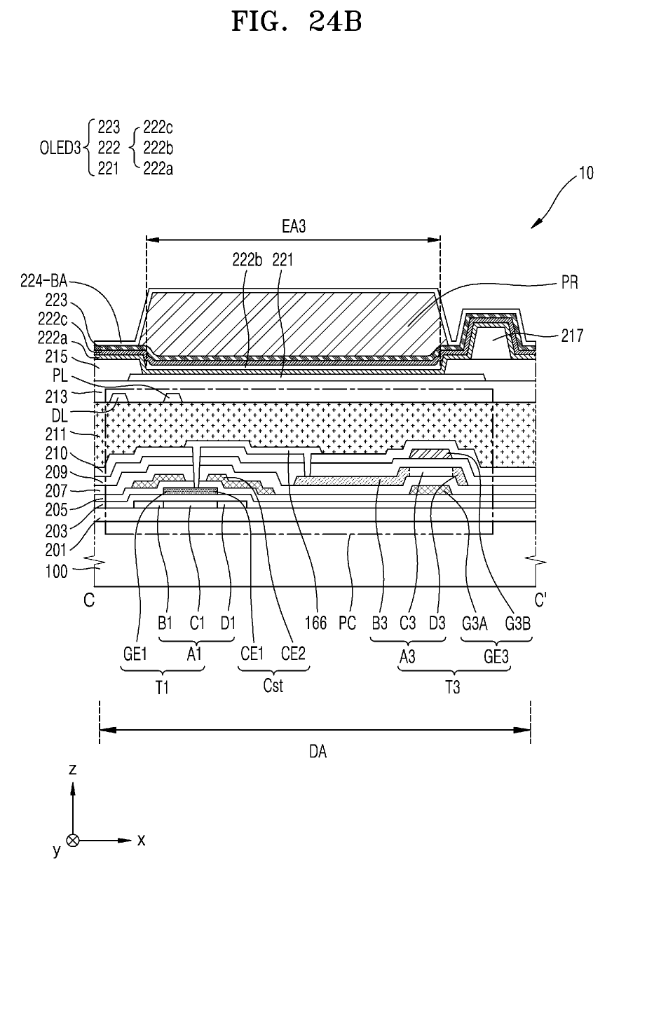

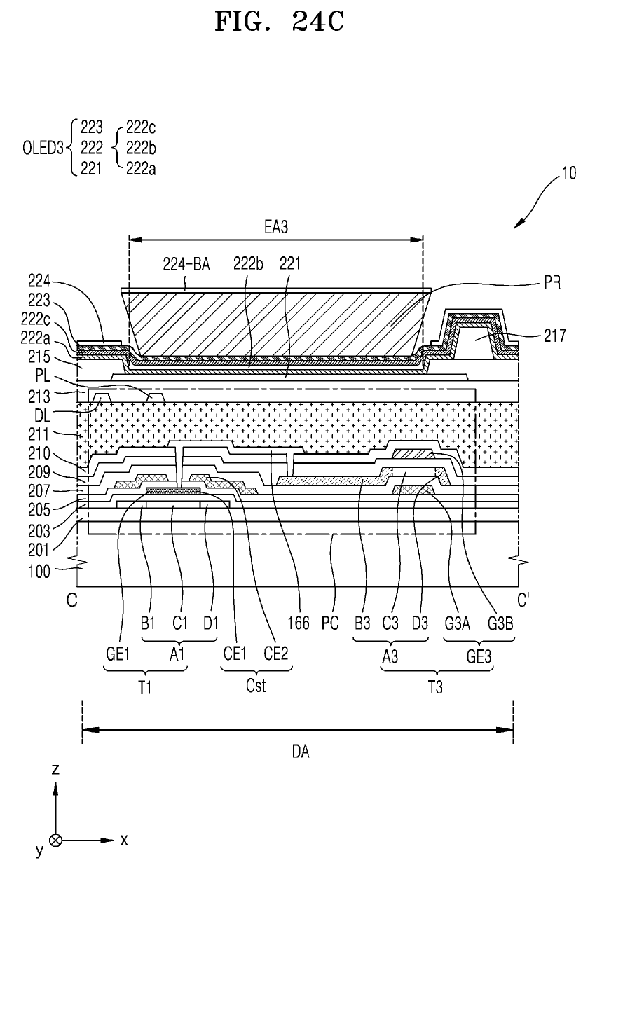

FIGS. 24A to 24C are schematic cross-sectional views showing some of the method of manufacturing the display device according to another embodiment. In FIG. 24, the same reference numerals as those in FIG. 8 denote the same components.

Referring to FIG. 24A, to form the auxiliary electrode 224, a second raw material 224-BA, which is an auxiliary electrode-forming material, may be disposed on the second electrode 223. In this case, the second raw material 224-BA may be coated on the second electrode 223 entirely. In this case, in the case where the auxiliary electrode 224 includes the same material as the material of the second electrode 223, the auxiliary electrode 224 may be integrally formed with the second electrode 223 and then the second raw material 224-BA disposed on the third emission area EA3 may be removed. In this case, the second raw material 224-BA disposed in the third emission area EA3 may be entirely removed or only partially removed. In this case, a sum of the thickness of the auxiliary electrode 224 and thickness of the second electrode 223 may be less in a region disposed in the third emission area EA3 than in other regions. However, hereinafter, for convenience of description, a case where the second electrode 223 and the auxiliary electrode 224 are formed through different processes is mainly described in detail.

The second raw material 224-BA is disposed on the second electrode 223, and then photoresist PR is disposed on the second raw material 224-BA, and the photoresist PR disposed in a portion corresponding to the third emission area EA3 may be removed. In this case, a portion of the second raw material 224-BA corresponding to the third emission area EA3 may be exposed to the outside through an opening area defined by the photoresist PR. In this case, a portion of the second raw material 224-BA exposed to the outside through the opening area of the photoresist PR may be removed through etching and the like. In contrast, the second raw material 224-BA under the photoresist PR may not be removed. In this case, the second raw material 224-BA under the photoresist PR excluding the third emission area EA3 is disposed on the bank layer 215 to form the auxiliary electrode 224. In this case, the auxiliary electrode 224 may not overlap the third emission area EA3. The auxiliary electrode 224 is not disposed in the first emission area and the second emission area (i.e., is offset from the first emission area and the second emission area), and may be disposed on the bank layer 225 excluding the first emission area and the second emission area.

Although FIG. 24A shows the boundary of the cross-section of the photoresist PR is a straight line, the boundary is not limited thereto and the boundary may be an oblique line as the boundary of the cross-section of the photoresist PR shown in FIGS. 24B or 24C described below.

Referring to FIG. 24B, the photoresist PR may be disposed on the second electrode 223 corresponding to the opening area (or the third emission area EA3) of the bank layer 215. The photoresist PR is provided in plurality, and the photoresists PR may be respectively disposed only the emission areas and disposed in island shapes to be apart from each other in the entire surface of the display area DA shown in FIG. 6. In this case, the photoresist PR may be a positive photoresist. Then, the second raw material 224-BA may be disposed on the photoresist PR and the second electrode 223. In this case, the second raw material 224-BA may be integrally disposed on the photoresist PR and the second electrode 223, and be disposed on the entire surface of the display area DA of FIG. 6 like the second electrode 223. Then, when removing the photoresist PR, the second raw material 224-BA disposed on the photoresist PR may be removed together with the photoresist PR. The auxiliary electrode 224 is not disposed on a portion of the second electrode 223 on which the photoresist PR is disposed (i.e., is offset from the photoresist PR on the second electrode 223), and the auxiliary electrode 224 may be disposed on the bank layer 225 excluding the third emission area EA3. In this case, the auxiliary electrode 224 may not overlap the third emission area EA3. The auxiliary electrode 224 is not disposed in the first emission area and the second emission area (i.e., is offset from the first and second emission areas), and may be disposed on the bank layer 225 excluding the first emission area and the second emission area.

Referring to FIG. 24C, the photoresist PR may be disposed similarly to FIG. 24B. In this case, the photoresist PR may be a negative photoresist. The second raw material 224-BA may be disposed on the entire surface of the display area DA shown in FIG. 6. In this case, because the second raw material 224-BA is disconnected at the boundary of the photoresist PR, the auxiliary electrode 224 may be disposed in a portion of the display area DA excluding each emission area. Then, when removing the photoresist PR, the second raw material 224-BA on the photoresist PR may be removed together with the photoresist PR similarly to that described with reference to FIG. 24B. The auxiliary electrode 224 is not disposed on a portion of the second electrode 223 on which the photoresist PR is disposed (i.e., is offset from the photoresist PR on the second electrode 223), and the auxiliary electrode 224 may be disposed on the bank layer 225 excluding the third emission area EA3. In this case, the auxiliary electrode 224 may not overlap the third emission area EA3. The auxiliary electrode 224 is not disposed in the first emission area and the second emission area (i.e., is offset from the first and second emission areas), and may be disposed on the bank layer 225 excluding the first emission area and the second emission area.

The planar shape of the auxiliary electrode 224 may be equal or similar to the shape shown in FIGS. 8, 15, 16, 17, 18, and/or FIG. 20. In this case, a portion of the protective layer WAL shown in FIGS. 8, 15, 16, 17, 18, 19 and/or FIG. 20 may be an opening area in which the auxiliary electrode 224 is not formed.

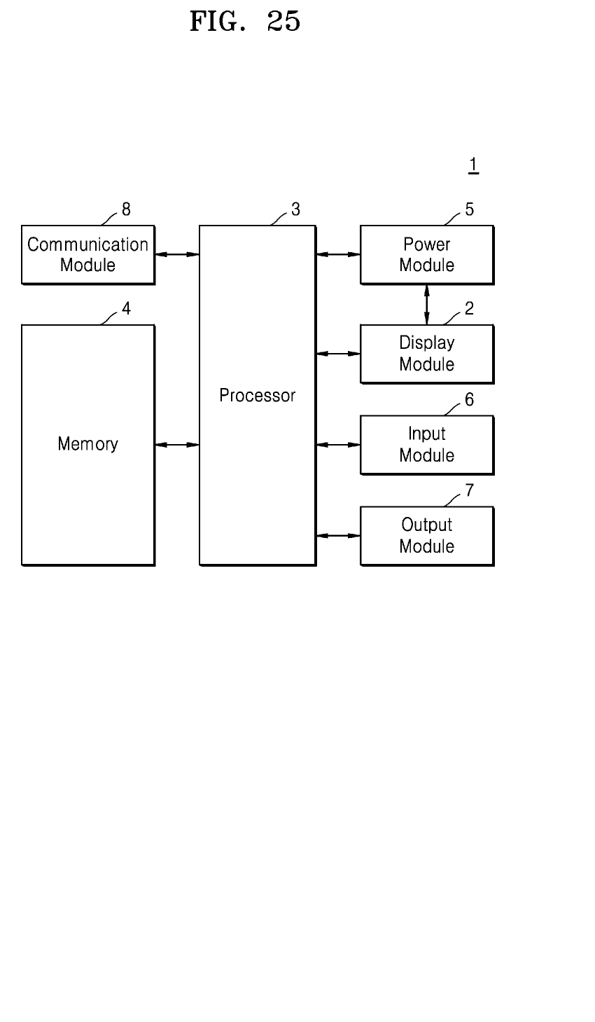

FIG. 25 is a block diagram of an electronic apparatus according to an embodiment.

Referring to FIG. 25, an electronic apparatus 1 according to an embodiment may include a display module 2 including a display panel, a processor 3, a memory 4, and a power module (e.g., power supply) 5.

The processor 3 may include at least one of a central processing unit (CPU), an application processor (AP), a graphic processing unit (GPU), a communication processor (CP), an image signal processor (ISP), and a controller. In an embodiment, the processor 3 may be divided into two or more portions in a functional or structural viewpoint. As an example, the processor 3 may include a main processor in the form of a first driving chip including a central processing unit, and an auxiliary processor in the form of a second driving chip including a controller that receives image signals from the main processor and processes the image signals to be suitable for an interface specification of the display module 2.

The memory 4 may include at least one of a non-volatile memory and a volatile memory. The memory 4 may store data information required for operations of the processor 3 or the display module 2. When the processor 3 executes an application stored in the memory 4, image data and/or an input control signal may be transferred to the display module 2, and the display module 2 may process provided signals and output image information through a display screen.

The power module 5 may include a power supply module such as a power adapter or a battery unit, and a power converting module converting power supplied by the power supply module and generating power required for operations of the electronic apparatus 1. Power conversion by the power converting module may include DC-DC conversion, AC-DC conversion, and DC-AC conversion, and is not limited thereto.

The electronic apparatus 1 may further include an input module (e.g., input interface) 6, a non-image output module (e.g., non-image output interface) 7, and/or a communication module (e.g., communication interface) 8.

The input module 6 may provide input information to the processor 3 and/or the display module 2. The input module 6 may include not only a physical button, a keyboard, and a microphone, but also various kinds of sensor modules. Examples of sensor modules may include not only touch sensors, pressure sensors, distance sensors, position sensors, digitizers, motion recognition sensors, camera sensors, photodetectors, photoelectric conversion sensors, temperature sensors, but also biometric sensors such as blood pressure sensors, blood sugar sensors, electrocardiogram sensors, and heart rate sensors.

The non-image output module 7 may receive information other than images received from the processor 3 and may provide the information to a user. Examples of non-image output module 7 include an audio module, a haptic module, a light-emitting module, and the like, and may include other functional modules unique to the electronic apparatus (e.g., a cooling module of a refrigerator, and the like).

The communication module 8 is a module responsible for transmission/reception of information between the electronic apparatus 1 and an external apparatus, and may include a receiver and a transmitter. The communication module 8 may include various wireless communication modules such as a mobile communication module, a Wi-Fi module, a Bluetooth module, or various wired communication modules.

At least one of the elements of the electronic apparatus 1 may be included inside the display device according to the embodiments. In addition, some of individual modules functionally included in one module may be included in the display device, and other some may be provided separately from the display device. As an example, the display device may include the display module 2, and the processor 3, the memory 4, and the power module 5 may be provided in the form of a different apparatus, which is not the display device, within the electronic apparatus 1. As another example, the power module 5 may be prepared in the display device, and may supply power to the processor 3 and the memory 4 provided in the electronic apparatus 1, which is not the display device, and is not limited to the above examples.

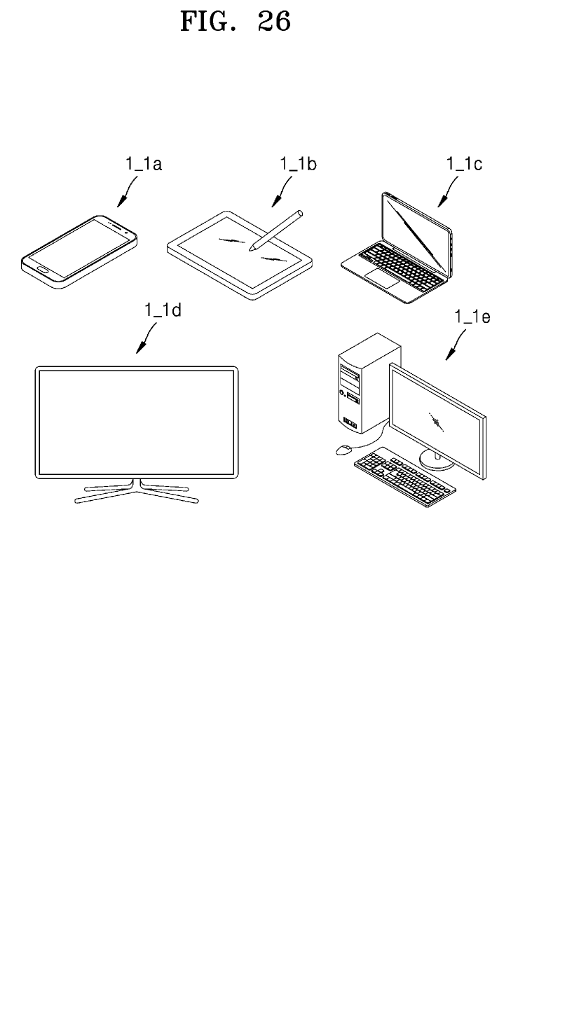

FIGS. 26 to 28 are schematic views of an electronic apparatus according to various embodiments. FIGS. 26 to 28 show examples of various electronic apparatuses employing the display device according to the embodiments.

FIG. 26 shows, as an example of the electronic apparatus, a smartphone 1_1a, a tablet personal computer (PC) 1_1b, a laptop 1_1c, and a TV 1_1d, and a desk monitor 1_1e.

The smartphone 1_1a may include an input module such as a touch sensor and the like, and a communication module in addition to the display module 2. The smartphone 1_1a may process information received through the communication module or other input modules and display the information through the display module of the display device.

Similar to the smartphone 1_1a, the tablet personal computer (PC) 1_1b, the laptop 1_1c, the TV 1_1d, and the desk monitor 1_1e may include the display module and the input module and may further include the communication module depending on a case.

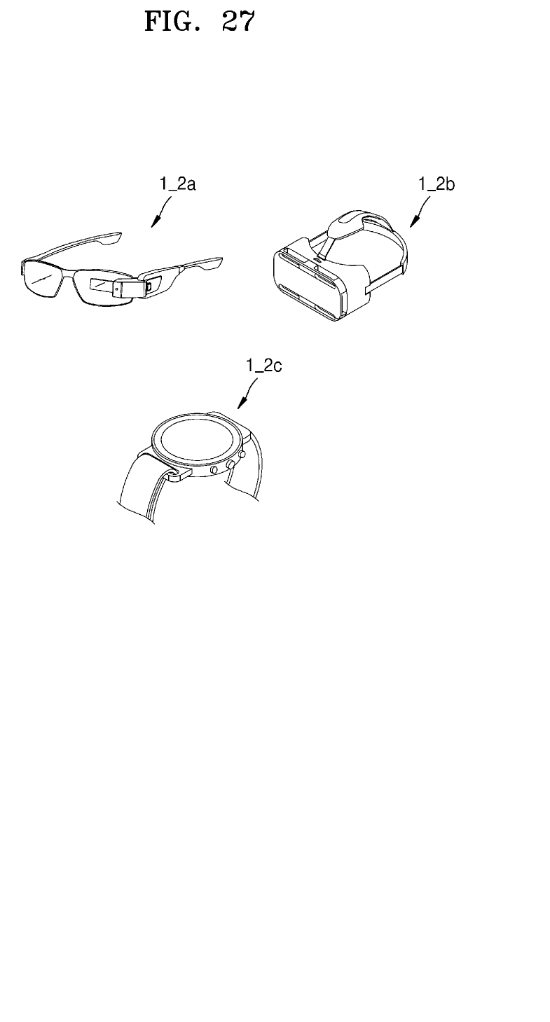

FIG. 27 shows an example in which the electronic apparatus including the display module is applied to a wearable electronic apparatus. The wearable electronic apparatus may include a smartglasses 1_2a, a head mount display 1_2b, a smartwatch 1_2c, and the like.

The smartglasses 1_2a and the head mount display 1_2b may include a display module emitting display images and a reflector reflecting an emitted display screen and providing the same to a user’s eyes, and may provide, through this, a user with screens of virtual reality or augmented reality.

The smartwatch 1_2c may include a biometric sensor as an input unit and provide, through the display module, a user with bio information recognized through the biometric sensor.

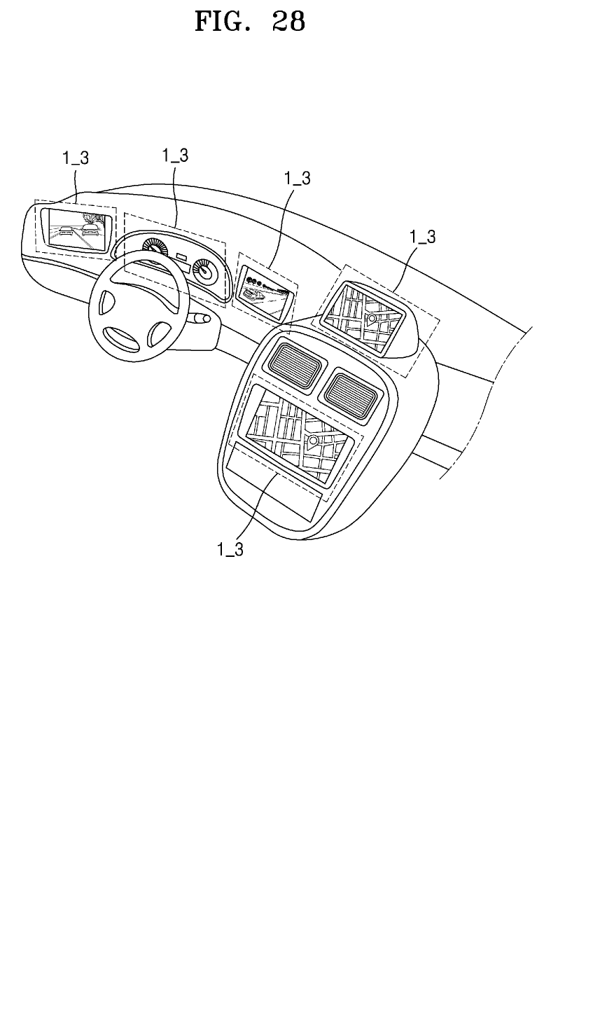

FIG. 28 shows an example in which the electronic apparatus including the display module is applied to a vehicle. As an example, an electronic apparatus 1_3 may be applied to an instrument board, a center facia or the like of an automobile, or may be applied to a center information display (CID) disposed on a dashboard of an automobile or a room mirror display replacing a side mirror.

Electronic apparatuses to which display devices according to the embodiments are applied may include not only apparatuses that mainly display screens, such as billboards, electronic boards, and game consoles, but also various home appliances that display information through display modules, such as refrigerators, washing machines, dryers, air conditioners, and robot cleaners. In addition, in the case where the display module has a function of transmitting light, the display module may be applied to electronic apparatuses such as smart windows or transparent display devices that display a background and a display image together. The kinds of electronic apparatuses according to the embodiments are not limited to those exemplified above, and the embodiments may be applied to various other electronic apparatuses not exemplified.

While aspects of example embodiments have been particularly shown and described, it will be understood that various changes in form and details may be made therein without departing from the spirit and scope of the following claims.

What is claimed is:

1. A display device comprising:
a substrate comprising a display area and a peripheral area that surrounds at least a portion of the display area;
a plurality of display elements spaced apart in the display area of the substrate, each of the plurality of display elements comprising a first electrode, an intermediate layer, and a second electrode sequentially stacked;
a bank layer on the first electrode of a first display element of the plurality of display elements and exposing a portion of the first electrode;
a protective layer on the second electrode on the portion of the first electrode exposed through the bank layer; and
an auxiliary electrode on and connected to the second electrode, wherein the auxiliary electrode is offset from the protective layer.

2. The display device of claim 1, wherein the auxiliary electrode comprises a same material as the second electrode.

3. The display device of claim 1, wherein the auxiliary electrode and the second electrode comprise different materials.

4. The display device of claim 1, wherein at least a portion of a planar shape of the auxiliary electrode has an island shape, a mesh shape, a serpentine shape, and/or a line shape.

5. The display device of claim 1, wherein a planar shape of a region through which the bank layer exposes the first electrode is inside a planar shape of the protective layer.

6. The display device of claim 1, wherein the protective layer shields at least one of the plurality of display elements.

7. The display device of claim 1, wherein the auxiliary electrode comprises:
a plurality of first auxiliary electrodes; and
a second auxiliary electrode connecting one of the plurality of first auxiliary electrodes to another of the plurality of first auxiliary electrodes.

8. The display device of claim 1, wherein at least a portion of a planar shape of the protective layer has an island shape, a line shape, a serpentine shape, and/or a mesh shape.

9. A method of manufacturing a display device, the method comprising:
sequentially disposing, on a substrate, a first electrode, a bank layer exposing at least a portion of the first electrode, an intermediate layer, and a second electrode;
disposing a protective layer on a first portion of the second electrode and the first electrode exposed through the bank layer; and
disposing an auxiliary electrode on a second portion of the second electrode that is offset from the first electrode exposed through the bank layer, wherein the auxiliary electrode is formed by disposing, on the second portion of the second electrode, an auxiliary electrode-forming material that forms the auxiliary electrode.

10. The method of claim 9, wherein the disposing of the protective layer comprises:
disposing a first mask defining a first opening to face the bank layer, wherein the first opening corresponds to the first portion of the second electrode; and
forming the protective layer on the first portion of the second electrode by passing a first deposition material through the first opening.

11. The method of claim 9, wherein the disposing of the protective layer comprises disposing, on the first portion of the second electrode, a protective layer-forming material using inkjet printing.

12. The method of claim 9, wherein the disposing of the protective layer on the portion of the second electrode disposed on the first electrode comprises:
disposing photoresist on an entire surface of the second electrode;
forming an opening area in the photoresist to correspond to the first portion of the second electrode; and
disposing a protective layer-forming material in the opening area.

13. The method of claim 9, wherein the disposing of the protective layer comprises:
disposing a protective layer-forming material on an entire surface of the second electrode;
disposing a blocking layer on a portion of the protective layer-forming material corresponding to the first portion of the second electrode; and
removing a remaining portion of the protective layer-forming material other than the portion of the protective layer-forming material disposed under the blocking layer.

14. The method of claim 9, wherein at least a portion of a planar shape of the auxiliary electrode and/or at least a portion of a planar shape of the protective layer has an island shape, a mesh shape, a serpentine shape, and/or a line shape.

15. The method of claim 9, wherein a planar shape of a region through which the bank layer exposes the first electrode is inside a planar shape of the protective layer.

16. The method of claim 9, wherein the disposing of the auxiliary electrode on the second portion of the second electrode comprises:
disposing a second mask to face the substrate, wherein the second mask defines a second opening corresponding to an entire surface of the second electrode;
supplying the auxiliary electrode-forming material toward the second mask; and
disposing, on the second electrode and the protective layer, the auxiliary electrode-forming material passing through the second opening.

17. The method of claim 9, wherein the disposing of the auxiliary electrode on the second portion of the second electrode comprises:
disposing a second mask defining a plurality of second openings to face the substrate, wherein at least one of the plurality of second openings corresponds to the second portion of the second electrode;
supplying the auxiliary electrode-forming material toward the second mask;
disposing, on the second portion of the second electrode, the auxiliary electrode-forming material passing through the plurality of second openings;
moving the second mask in one direction by a preset distance;
supplying the auxiliary electrode-forming material toward the second mask; and
disposing, in another region of the second electrode offset from the second portion, the auxiliary electrode-forming material passing through the plurality of second openings.

18. The method of claim 9, wherein the disposing of the auxiliary electrode on the second portion of the second electrode comprises disposing, on the second electrode and the protective layer, the auxiliary electrode-forming material using inkjet printing.

19. An electronic apparatus comprising a display device, wherein the display device comprises:
a substrate comprising a display area and a peripheral area that surrounds at least a portion of the display area;
a plurality of display elements spaced apart in the display area of the substrate, each of the plurality of display elements comprising a first electrode, an intermediate layer, and a second electrode sequentially stacked;
a bank layer on the first electrode of a first display element of the plurality of display elements and exposing a portion of the first electrode;
a protective layer on the second electrode on the portion of the first electrode exposed through the bank layer; and
an auxiliary electrode on and connected to the second electrode, wherein the auxiliary electrode is offset from the protective layer.

20. The electronic apparatus of claim 19, wherein at least a portion of a planar shape of the auxiliary electrode and/or at least a portion of a planar shape of the protective layer has an island shape, a mesh shape, a serpentine shape, and/or a line shape.
